(19) United States
(12) Patent Application Publication
(10) Pub. No.: US 2021/0159188 A1
(43) Pub. Date: May 27, 2021

(54) PACKAGE STRUCTURE AND METHOD FOR MANUFACTURING THE SAME

(71) Applicant: Advanced Semiconductor Engineering, Inc., Kaohsiung (TW)

(72) Inventors: Hsu-Nan FANG, Kaohsiung (TW); Yung-I YEH, Kaohsiung (TW)

(73) Assignee: Advanced Semiconductor Engineering, Inc., Kaohsiung (TW)

(21) Appl. No.: 16/693,191

(22) Filed: Nov. 22, 2019

(51) Int. Cl. H01L 23/00; H01L 25/065; H01L 23/31; H01L 25/00; H01L 21/56

(52) U.S. Cl. CPC H01L 23/562; H01L 25/0652; H01L 21/56; H01L 25/50; H01L 23/3135; H01L 23/3128

(57) ABSTRACT

A package structure includes a wiring structure, a first electronic device, a second electronic device, a protection material and a reinforcement structure. The first electronic device and the second electronic device are electrically connected to the wiring structure. The protection material is disposed between the first electronic device and the wiring structure and between the second electronic device and the wiring structure. The reinforcement structure is disposed on and contacts the first electronic device and the second electronic device. The reinforcement structure contacts the protection material.

### BACKGROUND

### 1. Field of the Disclosure

The present disclosure relates to a package structure and a manufacturing method, and to a package structure including a reinforcement structure, and a method for manufacturing the same.

### 2. Description of the Related Art

In a semiconductor assembly structure, a semiconductor package structure is mounted to a substrate, and a heat sink is attached to a top surface of the semiconductor package structure so as to dissipate the heat generated from the semiconductor device(s) in the semiconductor package during operation. However, when the heat sink is attached to the semiconductor package structure, a pressing force may be transmitted from the heat sink to the semiconductor package structure. Since a rigidity or stiffness of the semiconductor package structure is relatively low, a crack may be formed at the top surface of the semiconductor package structure. In addition, during a manufacturing process, several thermal process (e.g., reflow process) may be conducted to the semiconductor package structure, which may cause a warpage of the semiconductor package structure. Thus, a crack may be formed in the molding compound and/or underfill between the semiconductor devices. Such crack may extend or grow into the interior of the semiconductor package structure. If the crack reaches the substrate, the circuit portion in the substrate may be damaged or broken, which may result in an open circuit and render the semiconductor package structure inoperative. Thus, a yield of the semiconductor assembly structure may decrease.

### SUMMARY

In some embodiments, a package structure includes a wiring structure, a first electronic device, a second electronic device, a protection material and a reinforcement structure. The first electronic device and the second electronic device are electrically connected to the wiring structure. The protection material is disposed between the first electronic device and the wiring structure and between the second electronic device and the wiring structure. The reinforcement structure is disposed on and contacts the first electronic device and the second electronic device. The reinforcement structure contacts the protection material.

In some embodiments, a package structure includes a wiring structure, a first electronic device, a second electronic device, a protection material, a reinforcement structure and a buffer structure. The first electronic device and the second electronic device are electrically connected to the wiring structure. The protection material extends from a first space between the first electronic device and the wiring structure to a second space between the second electronic device and the wiring structure. The reinforcement structure is disposed on the first electronic device and the second electronic device. The buffer structure is disposed between the reinforcement structure and the protection material.

In some embodiments, a manufacturing method includes: (a) providing a wiring structure, wherein the wiring structure includes at least one dielectric layer and at least one circuit layer in contact with the dielectric layer; (b) electrically connecting a first electronic device and a second electronic device to the wiring structure; (c) forming a protection material in a first space between the first electronic device and the wiring structure and in a second space between the second electronic device and the wiring structure, wherein the protection material further extends into a gap between the first electronic device and the second electronic device; and (d) forming a reinforcement structure on the first electronic device, the second electronic device and the protection material.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a top view of a package structure according to some embodiments of the present disclosure.

FIG. 2 illustrates a cross-sectional view taken along line 2-2 of the package structure of FIG. 1.

FIG. 3 illustrates an enlarged view of a region “A” in FIG. 2.

FIG. 4 illustrates a cross-sectional view taken along line 4-4 of the package structure of FIG. 1.

FIG. 5 illustrates an enlarged view of a region of an example of a package structure according to some embodiments of the present disclosure.

FIG. 6 illustrates an enlarged view of a region of an example of a package structure according to some embodiments of the present disclosure.

FIG. 7 illustrates an enlarged view of a region of an example of a package structure according to some embodiments of the present disclosure.

FIG. 8 illustrates a cross-sectional view of an example of a package structure according to some embodiments of the present disclosure.

FIG. 9 illustrates a cross-sectional view of an example of a package structure according to some embodiments of the present disclosure.

FIG. 10 illustrates a cross-sectional view of an example of a package structure according to some embodiments of the present disclosure.

FIG. 11 illustrates a cross-sectional view of an example of a package structure according to some embodiments of the present disclosure.

FIG. 12 illustrates a cross-sectional view of an example of a package structure according to some embodiments of the present disclosure.

FIG. 13 illustrates a cross-sectional view of an example of a package structure according to some embodiments of the present disclosure.

FIG. 14 illustrates a cross-sectional view of an example of a package structure according to some embodiments of the present disclosure.

FIG. 15 illustrates a cross-sectional view of an example of a package structure according to some embodiments of the present disclosure.

FIG. 16 illustrates a cross-sectional view of an example of a package structure according to some embodiments of the present disclosure.

FIG. 17 illustrates a cross-sectional view of an example of a package structure according to some embodiments of the present disclosure.

FIG. 18 illustrates a cross-sectional view of an assembly structure according to some embodiments of the present disclosure.

FIG. 19 illustrates a cross-sectional view of an assembly structure according to some embodiments of the present disclosure.

FIG. 20 illustrates a cross-sectional view of an assembly structure according to some embodiments of the present disclosure.

FIG. 21 illustrates a cross-sectional view of an assembly structure according to some embodiments of the present disclosure.

FIG. 22 illustrates one or more stages of an example of a method for manufacturing an assembly structure according to some embodiments of the present disclosure.

FIG. 23 illustrates one or more stages of an example of a method for manufacturing an assembly structure according to some embodiments of the present disclosure.

FIG. 24 illustrates one or more stages of an example of a method for manufacturing an assembly structure according to some embodiments of the present disclosure.

FIG. 25 illustrates one or more stages of an example of a method for manufacturing an assembly structure according to some embodiments of the present disclosure.

FIG. 26 illustrates one or more stages of an example of a method for manufacturing an assembly structure according to some embodiments of the present disclosure.

FIG. 27 illustrates one or more stages of an example of a method for manufacturing an assembly structure according to some embodiments of the present disclosure.

FIG. 28 illustrates one or more stages of an example of a method for manufacturing an assembly structure according to some embodiments of the present disclosure.

FIG. 29 illustrates one or more stages of an example of a method for manufacturing an assembly structure according to some embodiments of the present disclosure.

FIG. 30 illustrates one or more stages of an example of a method for manufacturing an assembly structure according to some embodiments of the present disclosure.

FIG. 31 illustrates one or more stages of an example of a method for manufacturing an assembly structure according to some embodiments of the present disclosure.

FIG. 32 illustrates one or more stages of an example of a method for manufacturing an assembly structure according to some embodiments of the present disclosure.

FIG. 33 illustrates one or more stages of an example of a method for manufacturing an assembly structure according to some embodiments of the present disclosure.

FIG. 34 illustrates one or more stages of an example of a method for manufacturing an assembly structure according to some embodiments of the present disclosure.

FIG. 35 illustrates one or more stages of an example of a method for manufacturing an assembly structure according to some embodiments of the present disclosure.

FIG. 36 illustrates one or more stages of an example of a method for manufacturing an assembly structure according to some embodiments of the present disclosure.

FIG. 37 illustrates one or more stages of an example of a method for manufacturing an assembly structure according to some embodiments of the present disclosure.

FIG. 38 illustrates one or more stages of an example of a method for manufacturing an assembly structure according to some embodiments of the present disclosure.

FIG. 39 illustrates one or more stages of an example of a method for manufacturing an assembly structure according to some embodiments of the present disclosure.

FIG. 40 illustrates one or more stages of an example of a method for manufacturing an assembly structure according to some embodiments of the present disclosure.

FIG. 41 illustrates one or more stages of an example of a method for manufacturing an assembly structure according to some embodiments of the present disclosure.

FIG. 42 illustrates one or more stages of an example of a method for manufacturing an assembly structure according to some embodiments of the present disclosure.

FIG. 43 illustrates one or more stages of an example of a method for manufacturing an assembly structure according to some embodiments of the present disclosure.

FIG. 44 illustrates one or more stages of an example of a method for manufacturing an assembly structure according to some embodiments of the present disclosure.

FIG. 45 illustrates one or more stages of an example of a method for manufacturing an assembly structure according to some embodiments of the present disclosure.

FIG. 46 illustrates one or more stages of an example of a method for manufacturing an assembly structure according to some embodiments of the present disclosure.

FIG. 47 illustrates one or more stages of an example of a method for manufacturing an assembly structure according to some embodiments of the present disclosure.

FIG. 48 illustrates one or more stages of an example of a method for manufacturing an assembly structure according to some embodiments of the present disclosure.

FIG. 49 illustrates one or more stages of an example of a method for manufacturing an assembly structure according to some embodiments of the present disclosure.

FIG. 50 illustrates one or more stages of an example of a method for manufacturing an assembly structure according to some embodiments of the present disclosure.

FIG. 51 illustrates one or more stages of an example of a method for manufacturing an assembly structure according to some embodiments of the present disclosure.

FIG. 52 illustrates one or more stages of an example of a method for manufacturing an assembly structure according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

At least some embodiments of the present disclosure provide for a package structure which has an improved crack resistance. In some embodiments, an assembly structure includes such package structure so as to improve a reliability or a yield thereof. At least some embodiments of the present disclosure further provide for techniques for manufacturing the package structure and the assembly structure.

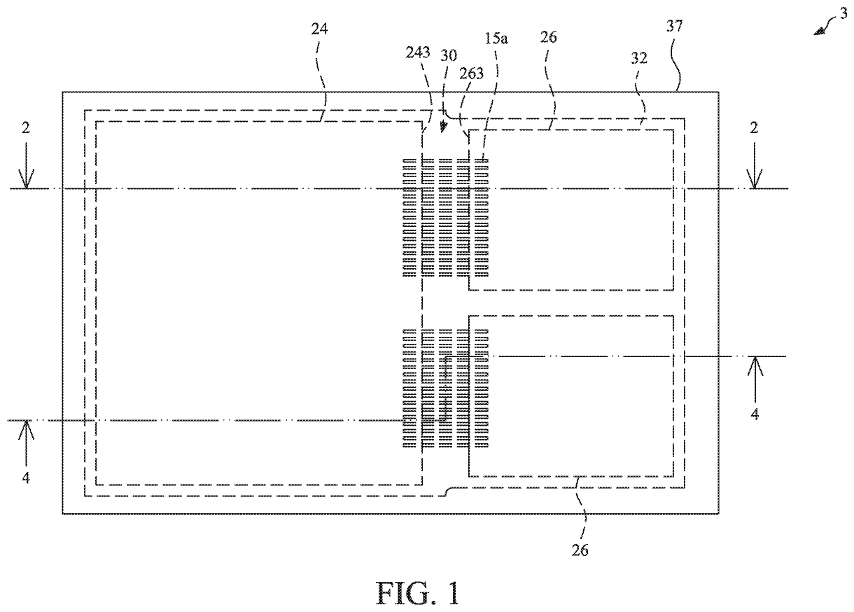

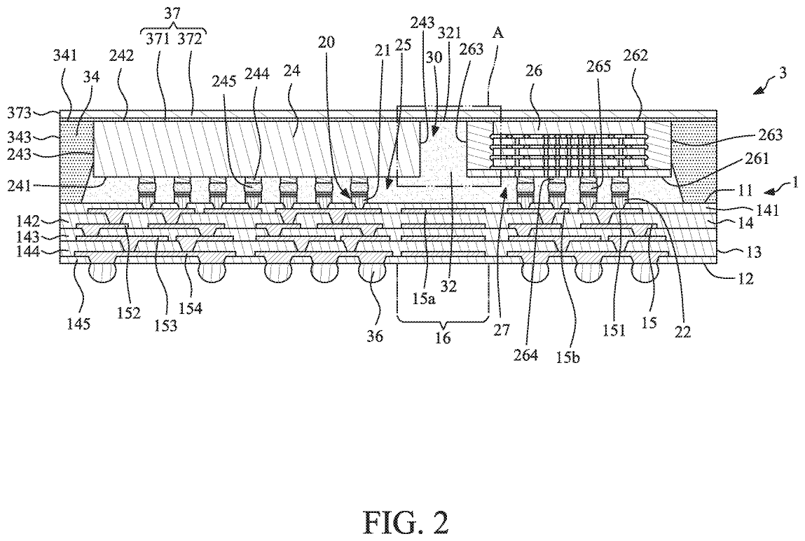

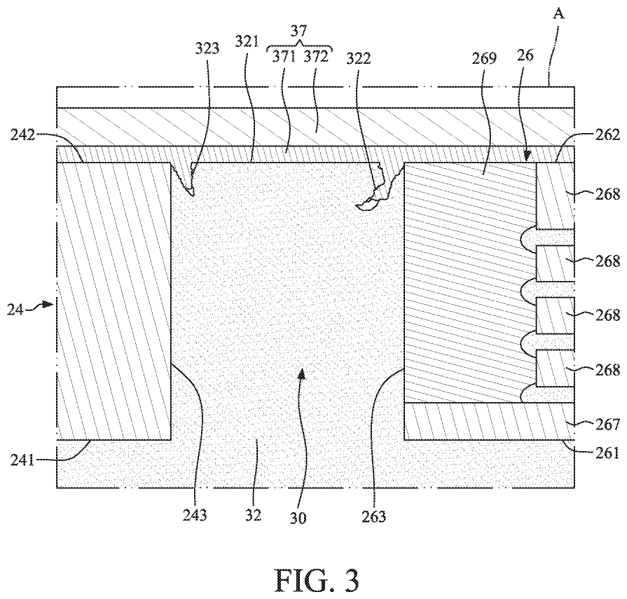

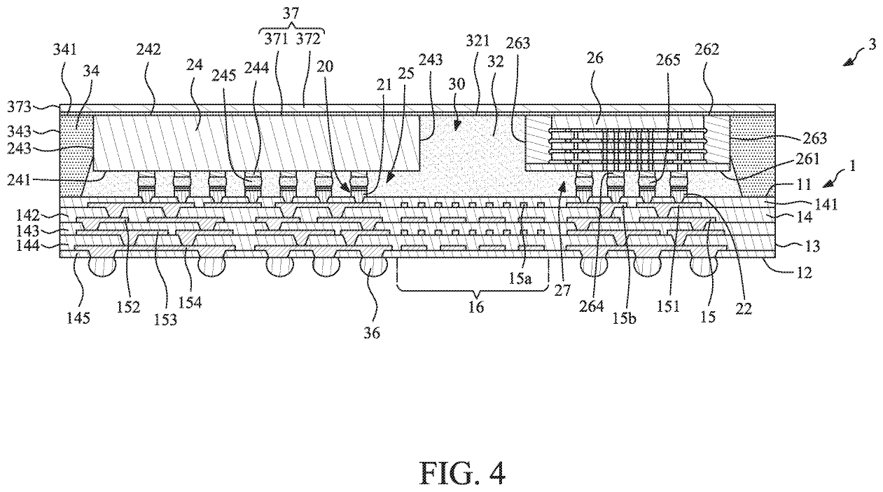

FIG. 1 illustrates a top view of a package structure 3 according to some embodiments of the present disclosure. FIG. 2 illustrates a cross-sectional view taken along line 2-2 of the package structure 3 of FIG. 1. FIG. 3 illustrates an enlarged view of a region “A” in FIG. 2. FIG. 4 illustrates a cross-sectional view taken along line 4-4 of the package structure 3 of FIG. 1. The package structure 3 includes a wiring structure 1, a first electronic device 24, a second electronic device 26, a reinforcement structure 37, a first protection material 32, an encapsulant 34 and a plurality of solder materials 36. As shown in FIG. 1, the package structure 3 may include one first electronic device 24 and two second electronic devices 26. However, the amounts of the first electronic device(s) 24 and the second electronic device(s) 26 are not limited in the present disclosure.

As shown in FIG. 2 and FIG. 4, the wiring structure 1 has a first surface 11, a second surface 12 opposite to the first surface 11, a lateral side surface 13 extending between the first surface 11 and the second surface 12, and a high density region 16 (or a fine line region) between the first electronic device 24 and the second electronic device 26. The wiring structure 1 may include at least one dielectric layer 14, at least one circuit layer 15 in contact with the dielectric layer 14, and a plurality of protrusion pads 20. For example, as shown in FIG. 2 and FIG. 4, the wiring structure 1 includes a first dielectric layer 141, a first circuit layer 151, a second dielectric layer 142, a second circuit layer 152, a third dielectric layer 143, a third circuit layer 153, a fourth dielectric layer 144, a fourth circuit layer 154, and a fifth dielectric layer 145. That is, the at least one dielectric layer 14 includes the first dielectric layer 141, the second dielectric layer 142, the third dielectric layer 143, the fourth dielectric layer 144 and the fifth dielectric layer 145. The at least one circuit layer 15 includes the first circuit layer 151, the second circuit layer 152, the third circuit layer 153 and the fourth circuit layer 154.

The first dielectric layer 141 may be a topmost dielectric layer or an outermost dielectric layer of the wiring structure 1. The first circuit layer 151 may be a topmost circuit layer or an outermost circuit layer of the wiring structure 1. A material of the first circuit layer 151 may include, for example, copper, another conductive metal, or an alloy thereof. A material of the first dielectric layer 141 may include an insulating material, a passivation material, a dielectric material or a solder resist material, such as, for example, a benzocyclobutene (BCB) based polymer or a polyimide (PI). In some embodiments, the first dielectric layer 141 may be made of a photoimageable material. In addition, the first surface 11 of the wiring structure 1 may be a top surface of the first dielectric layer 141. The first circuit layer 151 is disposed adjacent to the top surface of the first dielectric layer 141. In some embodiments, the first circuit layer 151 is embedded in the first dielectric layer 141, and is exposed from the top surface of the first dielectric layer 141. That is, the first dielectric layer 141 covers the first circuit layer 151, and defines a plurality of openings to expose portions of the first circuit layer 151.

Further, the first circuit layer 151 may include an interconnection portion 15a and a periphery portion 15b. The interconnection portion 15a is located in the high density region 16, and the periphery portion 15b is located outside the high density region 16 (e.g., a low density region). For example, the second electronic device 26 may be electrically connected to the first electronic device 24 through the interconnection portion 15a of the first circuit layer 151. The second electronic device 26 and the first electronic device 24 may be electrically connected to the solder materials 36 on the second surface 12 of the wiring structure 1 through the periphery portion 15b of the first circuit layer 151. A line width/line space (L/S) of the traces of the interconnection portion 15a may be less than an L/S of the traces of the periphery portion 15b. For example, an L/S of the traces of the interconnection portion 15a may be less than or equal to about 5 μm/about 5 μm, or less than or equal to about 2 μm/about 2 μm, or less than or equal to about 0.8 μm/about 0.8 μm. An L/S of the traces of the periphery portion 15b may be less than or equal to about 10 μm/about 10 μm, or less than or equal to about 7 μm/about 7 μm, or less than or equal to about 5 μm/about 5 μm.

The first dielectric layer 141 and the first circuit layer 151 may be disposed on the second dielectric layer 142. In addition, the second dielectric layer 142 may cover the second circuit layer 152. A portion (e.g., a via portion) of the first circuit layer 151 extends through the second dielectric layer 142 to electrically connect the second circuit layer 152. A material of the second dielectric layer 142 may be the same as or similar to the material of the first dielectric layer 141. The second circuit layer 152 may also include an interconnection portion located in the high density region 16, and a periphery portion located outside the high density region 16. In some embodiments, the via portion of the first circuit layer 151 may extend from the periphery portion, and they may be formed concurrently and integrally.

Similarly, the second dielectric layer 142 and the second circuit layer 152 may be disposed on the third dielectric layer 143. In addition, the third dielectric layer 143 may cover the third circuit layer 153. A portion (e.g., a via portion) of the second circuit layer 152 extends through the third dielectric layer 143 to electrically connect the third circuit layer 153. A material of the third dielectric layer 143 may be the same as or similar to the material of the second dielectric layer 142. The third circuit layer 153 may also include an interconnection portion located in the high density region 16, and a periphery portion located outside the high density region 16. In some embodiments, the via portion of the second circuit layer 152 may extend from the periphery portion, and they may be formed concurrently and integrally.

Similarly, the third dielectric layer 143 and the third circuit layer 153 may be disposed on the fourth dielectric layer 144. In addition, the fourth dielectric layer 144 may cover the fourth circuit layer 154. A portion (e.g., a via portion) of the third circuit layer 153 extends through the fourth dielectric layer 144 to electrically connect the fourth circuit layer 154. A material of the fourth dielectric layer 144 may be the same as or similar to the material of the third dielectric layer 143. The fourth circuit layer 154 may also include an interconnection portion located in the high density region 16, and a periphery portion located outside the high density region 16.

The fourth dielectric layer 144 and the fourth circuit layer 154 may be disposed on the fifth dielectric layer 145. A portion (e.g., a via portion) of the fourth circuit layer 154 extends through the fifth dielectric layer 145 to be exposed from a bottom surface of the fifth dielectric layer 145 (e.g., the second surface 12 of the wiring structure 1). A material of the fifth dielectric layer 145 may be the same as or similar to the material of the fourth dielectric layer 144. As shown in FIG. 2 and FIG. 4, the second electronic device 26 may be electrically connected to the first electronic device 24 through the interconnection portions 15a of the circuit layers 15 (including, for example, the interconnection portions 15a of the first circuit layer 151, the second circuit layer 152, the third circuit layer 153 and the fourth circuit layer 154). The second electronic device 26 and the first electronic device 24 may be electrically connected to the solder materials 36 through the via portions of the periphery portions 15b of the circuit layers 15 (including, for example, the periphery portions 15b of the first circuit layer 151, the second circuit layer 152, the third circuit layer 153 and the fourth circuit layer 154).

The protrusion pads 20 may be disposed on and protrude from the first dielectric layer 141 (e.g., the topmost dielectric layer or the outermost dielectric layer) of the wiring structure 1. The protrusion pads 20 may be disposed on and protrude from the first surface 11 of the wiring structure 1, and extend through the first dielectric layer 141 (e.g., the topmost dielectric layer or the outermost dielectric layer) to electrically connect the first circuit layer 151. The protrusion pads 20 may include a plurality of first protrusion pads 21 corresponding to the first electronic device 24 and a plurality of second protrusion pads 22 corresponding to the second electronic device 26.

The first electronic device 24 and the second electronic device 26 are disposed adjacent to the first surface 11 of the wiring structure 1 side by side, and are electrically connected to the circuit layer 15 of the wiring structure 1. The first electronic device 24 may be a semiconductor device such as an application specific integrated circuit (ASIC) die. As shown in FIG. 2 and FIG. 4, the first electronic device 24 may have a first surface 241, a second surface 242 opposite to the first surface 241, and a lateral side surface 243 extending between the first surface 241 and the second surface 242. Further, the first electronic device 24 may include a plurality of first electrical contacts 244 disposed adjacent to the first surface 241. The first electrical contacts 244 may be exposed or may protrude from the first surface 241 for electrical connection. The first electrical contacts 244 may be pads, bumps, studs, pillars or posts. In some embodiments, the first electrical contacts 244 of the first electronic device 24 may be electrically connected and physically connected to the first protrusion pads 21 through a plurality of solder materials 245. In other words, the first electronic device 24 may be electrically connected to the wiring structure 1 by flip-chip bonding. For example, the first electrical contacts 244 may include copper, gold, platinum, and/or other suitable material.

The second electronic device 26 may be a semiconductor device such as a high bandwidth memory (HBM) die or an ASIC die. As shown in FIG. 2 and FIG. 4, the second electronic device 26 may have a first surface 261, a second surface 262 opposite to the first surface 261, and a lateral side surface 263 extending between the first surface 261 and the second surface 262. Further, the second electronic device 26 may include a plurality of second electrical contacts 264 disposed adjacent to the first surface 261. The second electrical contacts 264 may be exposed or may protrude from the first surface 261 for electrical connection. The second electrical contacts 264 may be pads, bumps, studs, pillars or posts. In some embodiments, the second electrical contacts 264 of the second electronic device 26 may be electrically connected and physically connected to the second protrusion pads 22 through a plurality of solder materials 265. In other words, the second electronic device 26 may be electrically connected to the wiring structure 1 by flip-chip bonding. For example, the second electrical contact 264 may include copper, gold, platinum, and/or other suitable material.

The first protection material 32 (e.g., an underfill) is disposed in the first space 25 between the first electronic device 24 and the wiring structure 1 and the second space 27 between the second electronic device 26 and the wiring structure 1 so as to cover and protect the joints formed by the first electrical contacts 244, the first protrusion pads 21 and the solder materials 245, and the joints formed by the second electrical contacts 264, the second protrusion pads 22 and the solder materials 265. In some embodiments, the first protection material 32 may extend from the first space 25 to the second space 27. In addition, the first protection material 32 may further extend into a gap 30 between the lateral side surface 243 of the first electronic device 24 and the lateral side surface 263 of the second electronic device 26. The gap 30 may be less than about 100 μm, less than about 80 μm, less than about 70 μm, less than about 60 μm, or less than about 50 μm. Thus, the first protection material 32 may fill the gap 30 due to capillarity. The first protection material 32 has a top surface 321.

The encapsulant 34 covers at least a portion of the first surface 11 of the wiring structure 1, at least a portion of the first electronic device 24, at least a portion of the second electronic device 26 and the first protection material 32. A material of the encapsulant 34 may be a molding compound with or without fillers. The encapsulant 34 has a first surface 341 (e.g., a top surface) and a lateral side surface 343. As shown in FIG. 2 and FIG. 4, the first surface 341 of the encapsulant 34, the second surface 242 of the first electronic device 24, the second surface 262 of the second electronic device 26 and the top surface 321 of the first protection material 32 in the gap 30 may be substantially coplanar with each other. However, in other embodiments, the top surface 321 of the first protection material 32 in the gap 30 may be recessed from the second surface 242 of the first electronic device 24 and/or the second surface 262 of the second electronic device 26. Thus, a portion of the encapsulant 34 may extend into the gap 30 between the first electronic device 24 and the second electronic device 26. In addition, the lateral side surface 343 of the encapsulant 34 may be substantially coplanar with the lateral side surface 13 of the wiring structure 1.

The reinforcement structure 37 is formed or disposed on the first surface 341 of the encapsulant 34, the second surface 242 of the first electronic device 24, the second surface 262 of the second electronic device 26 and the top surface 321 of the first protection material 32. In some embodiments, the reinforcement structure 37 may be formed by plating or coating such as physical vapor deposition (PVD). Thus, the reinforcement structure 37 covers and contacts the first surface 341 of the encapsulant 34, the second surface 242 of the first electronic device 24, the second surface 262 of the second electronic device 26 and the top surface 321 of the first protection material 32 directly. Further, a surface condition (e.g., a surface roughness or a surface flatness) of a bottom surface of the reinforcement structure 37 is consistent with the surface conditions of the top surface 321 of the protection material 32, the second surface 242 of the first electronic device 24 and the second surface 262 of the second electronic device 26.

In some embodiments, the reinforcement structure 37 may include at least one metal layer. For example, the reinforcement structure 37 may include a first metal layer 371 and a second metal layer 372. The first metal layer 371 is disposed on the first surface 341 of the encapsulant 34, the second surface 242 of the first electronic device 24, the second surface 262 of the second electronic device 26 and the top surface 321 of the first protection material 32. The second metal layer 372 is disposed on the first metal layer 371. In some embodiments, the first metal layer 371 may be a titanium layer formed by PVD, and the second metal layer 372 may be a copper layer formed by PVD. In some embodiments, the reinforcement structure 37 may further include a third metal layer disposed on the second metal layer and a fourth metal layer disposed on the third metal layer. The third metal layer may be a copper layer formed by plating, and the fourth metal layer may be a titanium layer, a stainless steel layer, or a nickel layer formed by PVD.

As shown in FIG. 2 and FIG. 4, a lateral side surface 373 of the reinforcement structure 37 is substantially coplanar with the lateral side surface 343 of the encapsulant 34 and the lateral side surface 13 of the wiring structure 1. In addition, a thickness of the reinforcement structure 37 is equal to or greater than 4 μm, equal to or greater than 10 μm, or equal to or greater than 15 μm.

The solder materials 36 (e.g., solder balls) are disposed adjacent to the second surface 12 of the wiring structure 1 for external connection. As shown in FIG. 2 and FIG. 4, the solder materials 36 are disposed on the exposed portions (e.g., the bottom portions of the via portions) of the fourth circuit layer 154.

As shown in FIG. 3, the second electronic device 26 may include a logic die 267, four dynamic random access memories (DRAMs) 268 and a molding compound 269. The DRAMs 268 are stacked on one another and on the logic die 267. The molding compound 269 covers the DRAMs 268 and a portion of the logic die 267. In some embodiments, the first protection material 32 may have at least one crack (including, for example, a crack 322 and a crack 323) on the top surface 321 of the protection material 32. The crack 322 may be formed adjacent to a boundary between the first protection material 32 and the lateral side surface 263 of the second electronic device 26. The crack 323 may be formed adjacent to a boundary between the first protection material 32 and the lateral side surface 243 of the first electronic device 24. Such cracks 322, 323 may be formed during a grinding process, and may not extend through the first protection material 32. During a subsequent process (e.g., a coating process), a portion of the reinforcement structure 37 (e.g., a portion of the first metal layer 371) may extend into the cracks 322, 323. The portion of the reinforcement structure 37 (e.g., the portion of the first metal layer 371) may or may not fill the cracks 322, 323.

In the embodiment illustrated in FIG. 1 to FIG. 4, the reinforcement structure 37 may increase the rigidity or stiffness of the package structure 3 so as to reduce a warpage of the package structure 3. In addition, if a crack is formed in the first protection material 32 and/or the encapsulant 34, the reinforcement structure 37 may prevent the crack from growing or extending downward. Thus, the reinforcement structure 37 may prevent the crack from reaching the wiring structure 1, and may protect the interconnection portion 15a of the circuit layer 15 from being damaged or broken. Therefore, the reliability and yield of the package structure 3 is improved. As shown in FIG. 3, a portion of the reinforcement structure 37 may extend into the cracks 322, 323 of the first protection material 32. Thus, the bonding force between the reinforcement structure 37 and the first protection material 32 is improved. In some embodiments, a thermal conductivity of the reinforcement structure 37 is relatively high (e.g., the reinforcement structure 37 is a good thermal conductor), thus, a heat dissipation efficiency of the package structure 3 is improved.

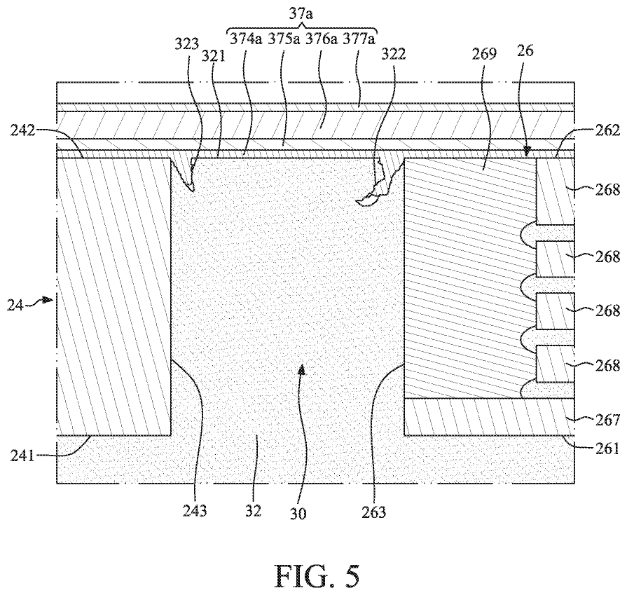

FIG. 5 illustrates an enlarged view of a region of an example of a package structure according to some embodiments of the present disclosure. The structure of FIG. 5 is similar to the of FIG. 3, except for a structure of the reinforcement structure 37a. As shown in FIG. 5, the reinforcement structure 37a may include a first metal layer 374a, a second metal layer 375a, a third metal layer 376a and a fourth metal layer 377a. The first metal layer 374a is disposed on the first surface 341 of the encapsulant 34, the second surface 242 of the first electronic device 24, the second surface 262 of the second electronic device 26 and the top surface 321 of the first protection material 32. The first metal layer 374a may be a titanium layer formed by PVD, and may have a thickness of about 0.2 μm to about 0.3 μm. The second metal layer 375a is disposed on the first metal layer 374a. The second metal layer 375a may be a copper layer formed by PVD, and may have a thickness of about 0.3 μm to about 0.5 μm. The third metal layer 376a is disposed on the second metal layer 375a. The third metal layer 376a may be a copper layer formed by plating, and may have a thickness of about 3 μm to about 5 μm. The fourth metal layer 377a is disposed on the third metal layer 376a. The fourth metal layer 377a may be a titanium layer or a stainless steel layer formed by PVD, and may have a thickness of about 0.5 μm to about 1 μm.

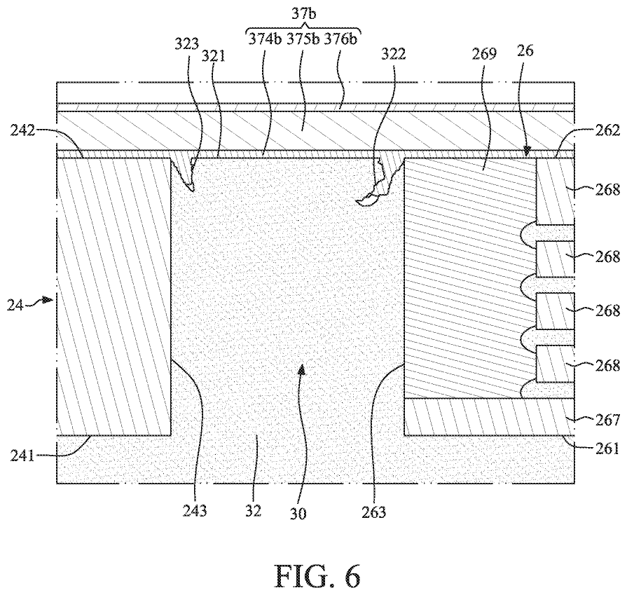

FIG. 6 illustrates an enlarged view of a region of an example of a package structure according to some embodiments of the present disclosure. The structure of FIG. 6 is similar to the of FIG. 3, except for a structure of the reinforcement structure 37b. As shown in FIG. 6, the reinforcement structure 37b may include a first metal layer 374b, a second metal layer 375b and a third metal layer 376b. The first metal layer 374b is disposed on the first surface 341 of the encapsulant 34, the second surface 242 of the first electronic device 24, the second surface 262 of the second electronic device 26 and the top surface 321 of the first protection material 32. The first metal layer 374b may be a titanium layer formed by PVD, and may have a thickness of about 0.2 μm to about 0.3 μm. The second metal layer 375b is disposed on the first metal layer 374b. The second metal layer 375b may be a copper layer formed by PVD, and may have a thickness of about 3 μm to about 5 μm. The third metal layer 376b is disposed on the second metal layer 375b. The third metal layer 376b may be a titanium layer or a stainless steel layer formed by PVD, and may have a thickness of about 0.5 μm to about 1 μm.

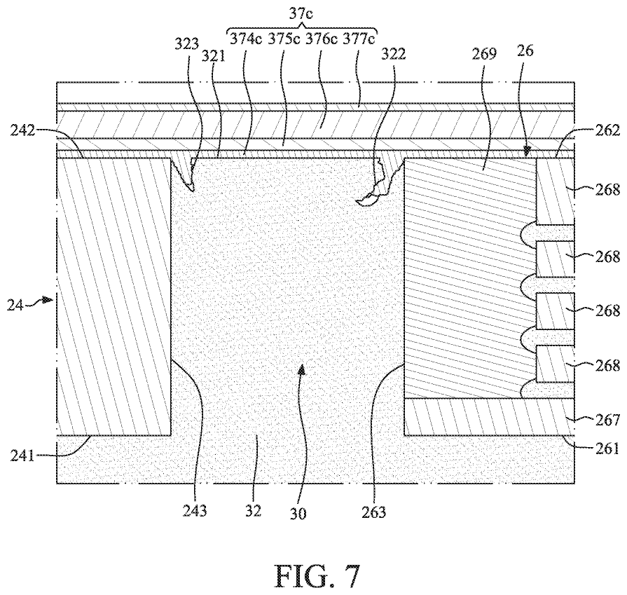

FIG. 7 illustrates an enlarged view of a region of an example of a package structure according to some embodiments of the present disclosure. The structure of FIG. 7 is similar to the of FIG. 3, except for a structure of the reinforcement structure 37c. As shown in FIG. 7, the reinforcement structure 37c may include a first metal layer 374c, a second metal layer 375c, a third metal layer 376c and a fourth metal layer 377c. The first metal layer 374c is disposed on the first surface 341 of the encapsulant 34, the second surface 242 of the first electronic device 24, the second surface 262 of the second electronic device 26 and the top surface 321 of the first protection material 32. The first metal layer 374c may be a titanium layer formed by PVD, and may have a thickness of about 0.2 μm to about 0.3 μm. The second metal layer 375c is disposed on the first metal layer 374c. The second metal layer 375c may be a copper layer formed by PVD, and may have a thickness of about 0.3 μm to about 0.5 μm. The third metal layer 376c is disposed on the second metal layer 375c. The third metal layer 376c may be a copper layer formed by plating, and may have a thickness of about 3 μm to about 5 μm. The fourth metal layer 377c is disposed on the third metal layer 376c. The fourth metal layer 377c may be a nickel layer formed by plating, and may have a thickness of about 2 μm to about 3 μm.

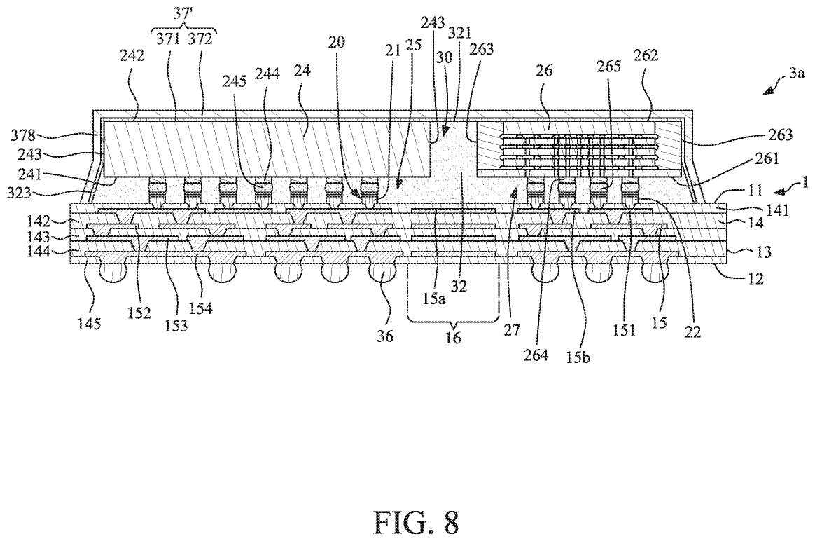

FIG. 8 illustrates a cross-sectional view of an example of a package structure 3a according to some embodiments of the present disclosure. The package structure 3a of FIG. 8 is similar to the package structure 3 of FIG. 2 and FIG. 4, except that the encapsulant 34 is omitted. Thus, a periphery portion 378 of the reinforcement structure 37′ further covers and contacts the lateral side surface 243 of the first electronic device 24, the lateral side surface 263 of the second electronic device 26 and an outer side surface 323 of the first protection material 32. In some embodiments, a bottom portion of the periphery portion 378 of the reinforcement structure 37′ may be physically or/and electrically connected to the wiring structure 1.

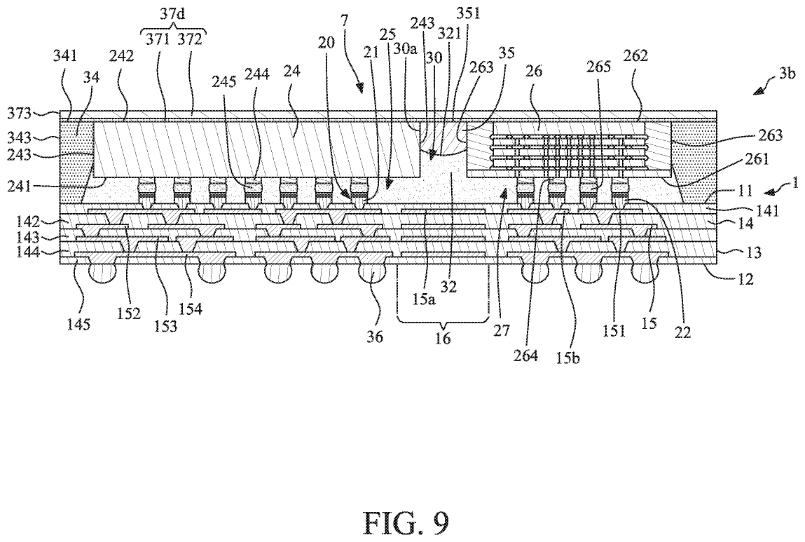

FIG. 9 illustrates a cross-sectional view of an example of a package structure 3baccording to some embodiments of the present disclosure. The package structure 3b of FIG. 9 is similar to the package structure 3 of FIG. 2 and FIG. 4, except for a structure of the reinforcement structure 7. As shown in FIG. 9, the first protection material 32 in the gap 30 may not reach to the level of the second surface 242 of the first electronic device 24 and/or the second surface 262 of the second electronic device 26. Thus, there is a groove 30a defined by the lateral side surface 243 of the first electronic device 24, the top surface 321 of the first protection material 32 and the lateral side surface 263 of the second electronic device 26. The groove 30a may be a portion of the gap 30. Further, the reinforcement structure 7 may include a first reinforcement portion 37d and a second reinforcement portion 35. The second reinforcement portion 35 may be disposed in the groove 30a (or in the gap 30). As shown in FIG. 9, the first surface 341 of the encapsulant 34, the second surface 242 of the first electronic device 24, the second surface 262 of the second electronic device 26 and a top surface 351 of the second reinforcement portion 35 may be substantially coplanar with each other. The first reinforcement portion 37d may be the same as the reinforcement portion 37 of FIG. 2 and FIG. 4, and may be disposed on and may contact the first surface 341 of the encapsulant 34, the second surface 242 of the first electronic device 24, the second surface 262 of the second electronic device 26 and the top surface 351 of the second reinforcement portion 35. A material of the first reinforcement portion 37d may be same as or different from a material of the second reinforcement portion 35. For example, the material of the second reinforcement portion 35 may be metal or polymer. In some embodiments, a Young's modulus of the second reinforcement portion 35 may be greater than a Young's modulus of the first reinforcement portion 37d; thus, the rigidity or stiffness of the package structure 3b is increased. In some embodiments, a Young's modulus of the second reinforcement portion 35 may be less than a Young's modulus of the first reinforcement portion 37d; thus, the second reinforcement portion 35 may be capable of a buffer structure disposed between the first reinforcement structure 37d and the first protection material 32, and may absorb the stress caused during the thermal cycles.

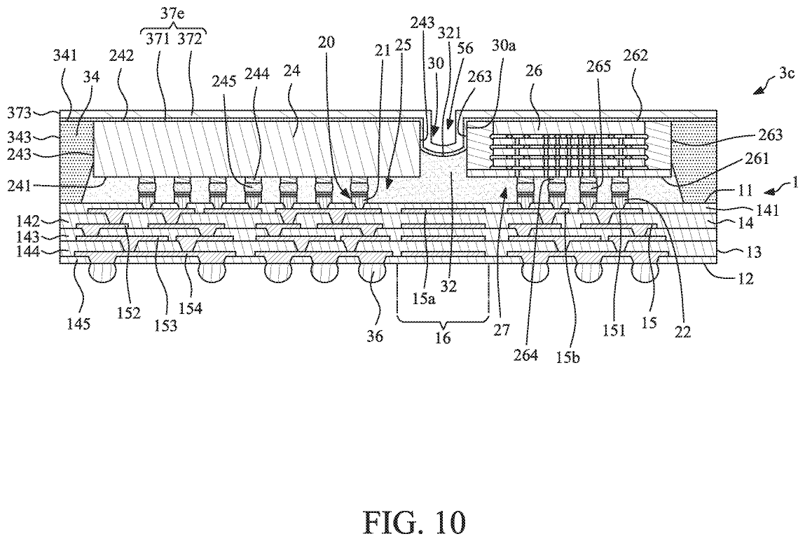

FIG. 10 illustrates a cross-sectional view of an example of a package structure 3c according to some embodiments of the present disclosure. The package structure 3c of FIG. 10 is similar to the package structure 3b of FIG. 9, except for a structure of the reinforcement structure 37e. As shown in FIG. 10, a portion of the reinforcement structure 37e extends into the groove 30a (or the gap 30) between the first electronic device 24 and the second electronic device 26. In addition, the portion of the reinforcement structure 37e in the groove 30a (or the gap 30) may define a trench 56. That is, the reinforcement structure 37e may not fill the groove 30a (or the gap 30).

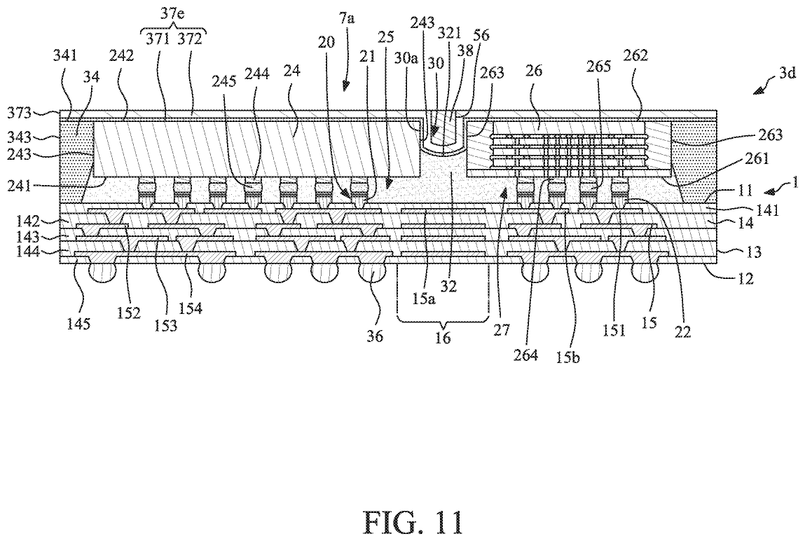

FIG. 11 illustrates a cross-sectional view of an example of a package structure 3d according to some embodiments of the present disclosure. The package structure 3d of FIG. 11 is similar to the package structure 3c of FIG. 10, except for a structure of the reinforcement structure 7a. The reinforcement structure 7a may include a first reinforcement portion 37e and a second reinforcement portion 38. The first reinforcement portion 37e may be the same as the reinforcement portion 37e of FIG. 10. The second reinforcement portion 38 may be disposed in the trench 56. A material of the second reinforcement portion 38 may be same as the material of the second reinforcement portion 35 of FIG. 9.

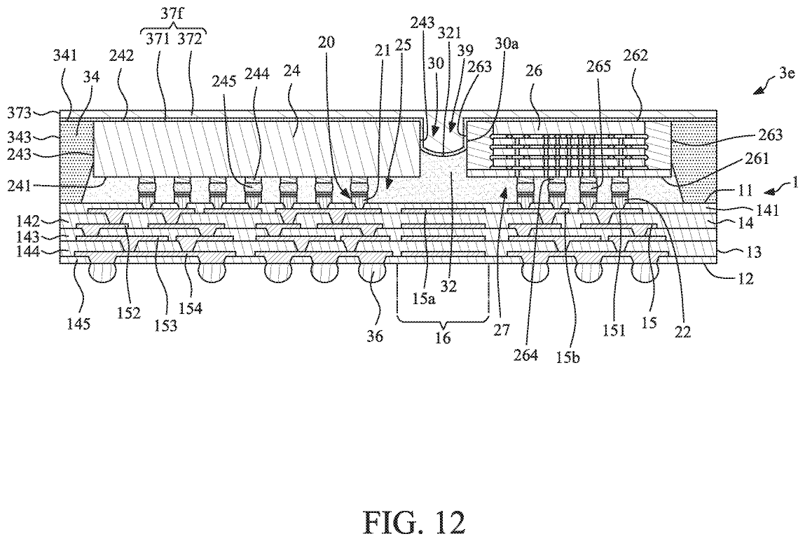

FIG. 12 illustrates a cross-sectional view of an example of a package structure 3e according to some embodiments of the present disclosure. The package structure 3e of FIG. 12 is similar to the package structure 3c of FIG. 10, except for a structure of the reinforcement structure 37f. A portion 39 of the reinforcement structure 37f may extend into the gap 30 to fill the groove 30a and contact the top surface 321 of the first protection material 32. The reinforcement structure 37f may be a monolithic structure. As shown in FIG. 12, the reinforcement structure 37f may be in a substantially “T” shape. Thus, the bonding force between the reinforcement structure 37f and the first electronic device 24 and the second electronic device 26 is improved. In addition, the rigidity or stiffness of the package structure 3e is further increased, and a heat dissipation efficiency of the package structure 3e is improved.

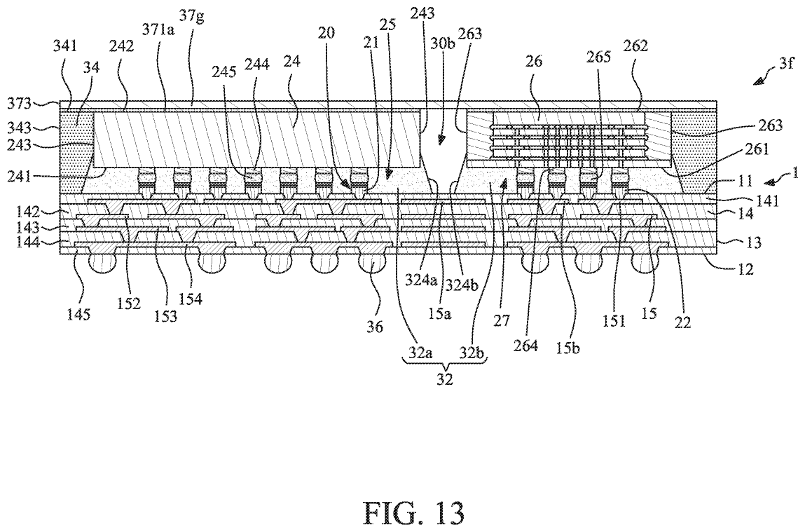

FIG. 13 illustrates a cross-sectional view of an example of a package structure 3f according to some embodiments of the present disclosure. The package structure 3f of FIG. 13 is similar to the package structure 3 of FIG. 2 and FIG. 4, except for a structure of a gap 30b. As shown in FIG. 13, the first protection material 32 may include a first portion 32a and a second portion 32b separated from the first portion 32a. The first portion 32a is disposed in the first space 25, and has an inner side surface 324a. The second portion 32b is disposed in the second space 27, and has an inner side surface 34b. The gap 30b is defined by the lateral side surface 243 of the first electronic device 24, the lateral side surface 263 of the second electronic device 26, the inner side surface 324a of the first portion 32a, the inner side surface 324b of the second portion 32b and a portion of the first surface 11 of the wiring structure 1. In addition, the reinforcement structure 37g of FIG. 13 may be a metal plate, and may be attached to the first surface 341 of the encapsulant 34, the second surface 242 of the first electronic device 24 and the second surface 262 of the second electronic device 26 through an adhesion layer 371a to cover the gap 30b. Thus, the gap 30b may be an empty space.

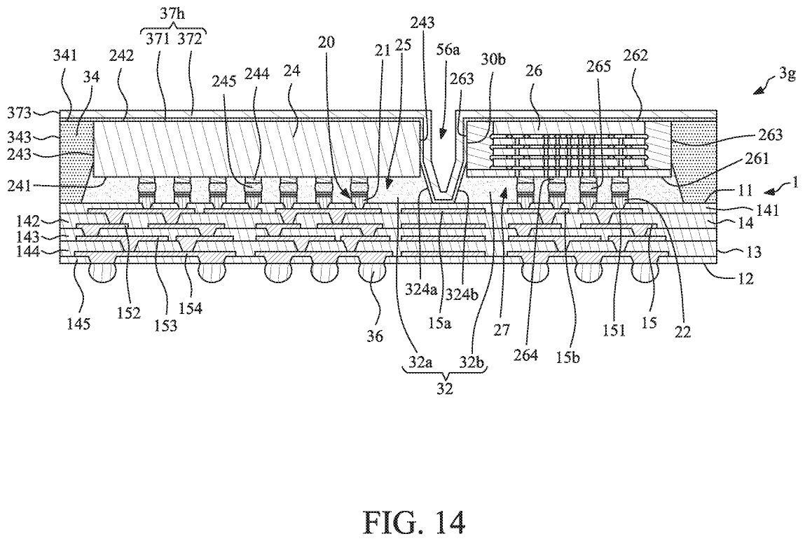

FIG. 14 illustrates a cross-sectional view of an example of a package structure 3g according to some embodiments of the present disclosure. The package structure 3g of FIG. 14 is similar to the package structure 3f of FIG. 13, except for a structure of a reinforcement structure 37h. The reinforcement structure 37h of FIG. 14 may be substantially similar to the reinforcement structure 37e of FIG. 10, and may extend into the gap 30b to contact the inner side surface 324a of the first portion 32a, the inner side surface 324b of the second portion 32b and the first surface 11 of the wiring structure 1. In addition, the portion of the reinforcement structure 37h in the gap 30b may define a trench 56a. That is, the reinforcement structure 37h may not fill the gap 30b.

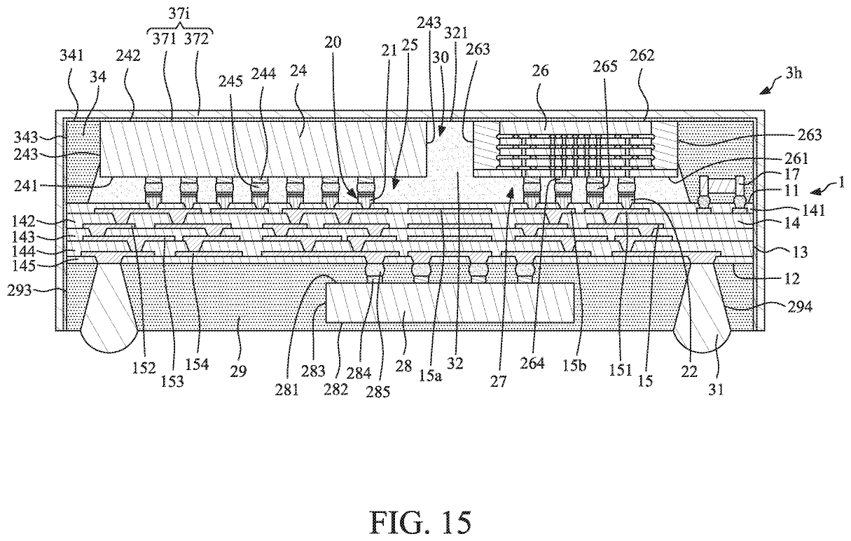

FIG. 15 illustrates a cross-sectional view of an example of a package structure 3h according to some embodiments of the present disclosure. The package structure 3h of FIG. 15 is similar to the package structure 3 of FIG. 2 and FIG. 4, except that the solder materials 36 are omitted, and a passive device 17, a third electronic device 28, a package body 29 and a plurality of external connectors 31 are further included. The passive device 17 is disposed adjacent to the first surface 11 of the wiring structure 1, and is electrically connected to the circuit layer 15 of the wiring structure 1. The passive device 17 may be a resistor, an inductor and/or a capacitor. Alternatively, the passive device 17 may be a resistor-inductor-capacitor (RLC) circuit.

The third electronic device 28 is disposed adjacent to the second surface 12 of the wiring structure 1, and is electrically connected to the circuit layer 15 of the wiring structure 1. The third electronic device 28 may be a semiconductor device such as an application specific integrated circuit (ASIC) die or a bridge die. As shown in FIG. 15, the third electronic device 28 may have a first surface 281, a second surface 282 opposite to the first surface 281, and a lateral side surface 283 extending between the first surface 281 and the second surface 282. Further, the third electronic device 28 may include a plurality of third electrical contacts 284 disposed adjacent to the first surface 281. The third electrical contacts 284 may be exposed or may protrude from the first surface 281 for electrical connection. In some embodiments, the third electrical contacts 284 of the third electronic device 28 may be electrically connected and physically connected to the exposed portions (e.g., the bottom portions of the via portions) of the fourth circuit layer 154 of the wiring structure 1 through a plurality of solder materials 285.

The package body 29 (e.g., a molding compound with or without fillers) may cover the third electronic device 28, an extend into a space between the third electronic device 28 and the wiring structure 1 to cover and protect the third electrical contacts 284 and the solder materials 285. The package body 29 may defines a plurality of opening 294 extending through the package body 29 and exposing the exposed portions (e.g., the bottom portions of the via portions) of the fourth circuit layer 154. The external connectors 31 (e.g., solder materials) are disposed in the openings 294 of the package body 29, and protrude beyond a bottom surface of the package body 29 for external connection.

As shown in FIG. 15, the reinforcement structure 37i is further disposed on and contacts the lateral side surface 343 of the encapsulant 34, the lateral side surface 13 of the wiring structure 1 and a lateral side surface 293 of the package body 29. The reinforcement structure 37i may be in a substantially cap structure. Thus, the bonding force between the reinforcement structure 37i and the first electronic device 24, the second electronic device 26, the wiring structure 1, the encapsulant 34 and the package body 29 is improved. In addition, the rigidity or stiffness of the package structure 3h is further increased, and a heat dissipation efficiency of the package structure 3h is improved.

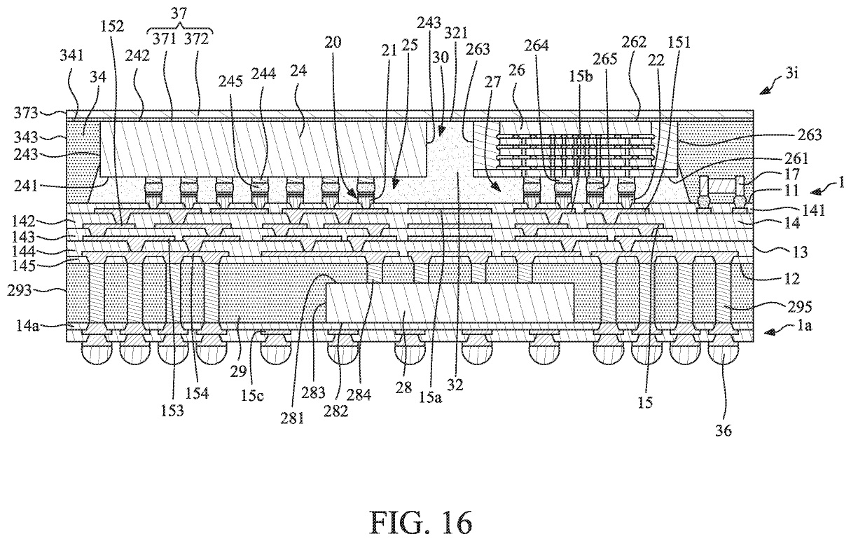

FIG. 16 illustrates a cross-sectional view of an example of a package structure 3i according to some embodiments of the present disclosure. The package structure 3i of FIG. 16 is similar to the package structure 3h of FIG. 15, except that the external connectors 31 are replaced by the a plurality of though vias 295, the solder materials 285 are omitted, and a lower wiring structure 1a is further included. As shown in FIG. 16, the though vias 295 and the third electrical contacts 284 of the third electronic device 28 may contact the exposed portions (e.g., the bottom portions of the via portions) of the fourth circuit layer 154 of the wiring structure 1. The though vias 295 may extend through the package body 29. The lower wiring structure 1a may be disposed on the bottom surface of the package body 29 and the second surface 282 of the third electronic device 28. The lower wiring structure 1a may be electrically connected to the wiring structure 1 through the though vias 295. The lower wiring structure 1a may include at least one dielectric layer 14a and at least one circuit layer 15c. The solder materials 36 (e.g., solder balls) are disposed adjacent to the bottom surface of the lower wiring structure 1a for external connection. In addition, the lateral side surface 373 of the reinforcement structure 37 is substantially coplanar with the lateral side surface 343 of the encapsulant 34 and the lateral side surface 13 of the wiring structure 1.

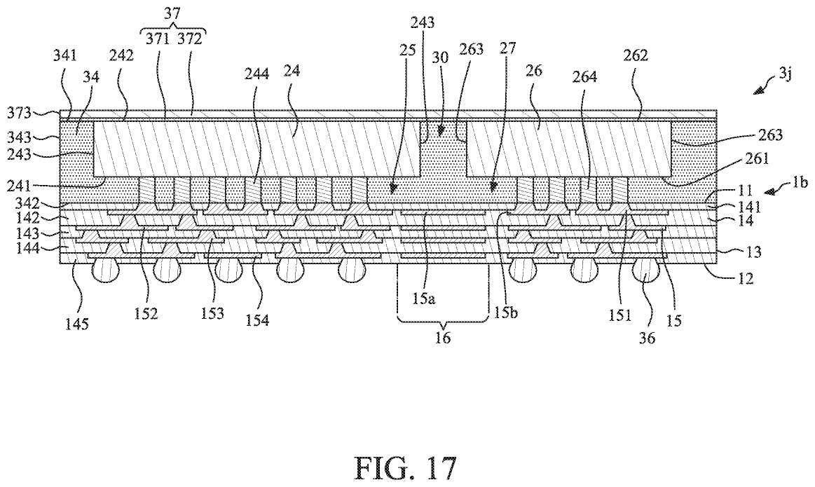

FIG. 17 illustrates a cross-sectional view of an example of a package structure 3j according to some embodiments of the present disclosure. The package structure 3j of FIG. 17 is similar to the package structure 3 of FIG. 2 and FIG. 4, and the differences are described as follows. The solder materials 245, 264 and the first protection material 32 may be omitted. The encapsulant 34 may extend from the first space 25 to the second space 27 to cover and protect the first electrical contacts 244 and the second electrical contacts 264. The encapsulant 34 has the first surface 341 and a second surface 342. The second surface 342 of the encapsulant 34 may be substantially coplanar with the bottom surfaces of the first electrical contacts 244 and the second electrical contacts 264. The wiring structure 1b is disposed on the second surface 342 of the encapsulant 34, and includes at least one dielectric layer 14 and at least one circuit layer 15 in contact with the dielectric layer 14. As shown in FIG. 17, the wiring structure 1b may include a first dielectric layer 141, a first circuit layer 151, a second dielectric layer 142, a second circuit layer 152, a third dielectric layer 143, a third circuit layer 153, a fourth dielectric layer 144, a fourth circuit layer 154, and a fifth dielectric layer 145.

For example, the first dielectric layer 141 may contact the encapsulant 34. The first circuit layer 151 may be disposed on the first dielectric layer 141. A portion (e.g., a via portion) of the first circuit layer 151 may extend through the first dielectric layer 141 to electrically connect the first electrical contacts 244 and the second electrical contacts 264. The second dielectric layer 142 may cover the first dielectric layer 141 and the first circuit layer 151. The second circuit layer 152 may be disposed on the second dielectric layer 142. A portion (e.g., a via portion) of the second circuit layer 152 may extend through the second dielectric layer 142 to electrically connect the first circuit layer 151. The third dielectric layer 143 may cover the second dielectric layer 142 and the second circuit layer 151. The solder materials 36 (e.g., solder balls) are disposed adjacent to the second surface 12 of the wiring structure 1b for external connection. As shown in FIG. 17, the solder materials 36 are disposed on the exposed portions of the fourth circuit layer 154.

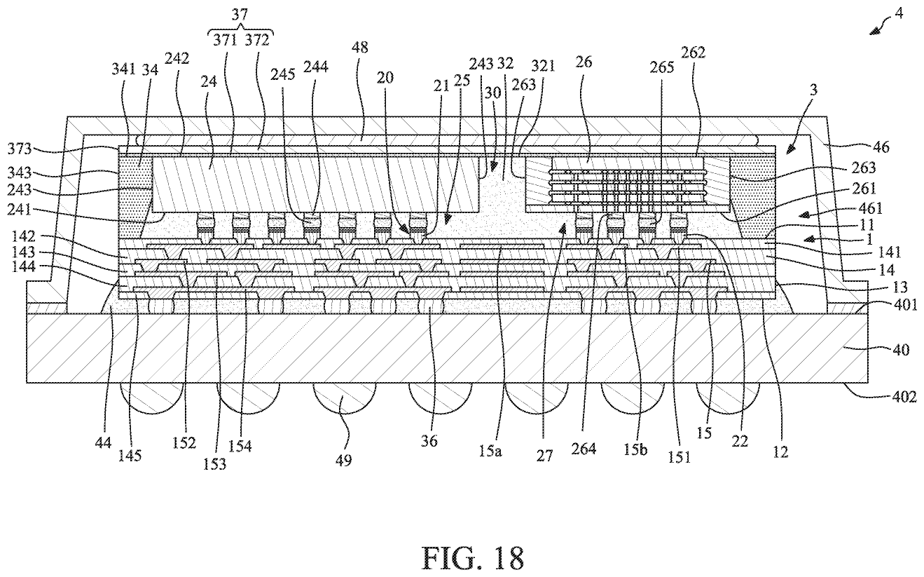

FIG. 18 illustrates a cross-sectional view of an assembly structure 4 according to some embodiments of the present disclosure. The assembly structure 4 may be a semiconductor package, and may include a base substrate 40, a package structure 3, a second protection material 44, a heat sink 46 and a plurality of external connectors 49.

The base substrate 40 may include a glass reinforced epoxy material (such as FR4), bismaleimide triazine (BT), epoxy resin, silicon, printed circuit board (PCB) material, glass, ceramic or photoimageable dielectric (PID) material. The base substrate 40 may have a first surface 401 and a second surface 402 opposite to the first surface 401. The package structure 3 of FIG. 18 may be same as or similar to the package structure 3 of FIG. 1 to FIG. 4. The package structure 3 may be electrically connected to the first surface 401 of the base substrate 40 through the solder materials 36. The second protection material 44 (e.g., an underfill) is disposed in a space between the package structure 3 and the base substrate 40 so as to cover and protect the solder materials 36.

The heat sink 46 may be a cap or hat structure, and may define a cavity 461 for accommodating the package structure 3. A material of the heat sink 46 may include metal such as copper, aluminum, and/or other suitable material. A portion of the heat sink 46 may be attached to the top surface of the package structure 3 through a thermal material 48 (e.g., thermal interface material (TIM)) so as to dissipate the heat generated by the first electronic device 24 and the second electronic device 26. Another portion (e.g., bottom portion) of the heat sink 46 may be attached to the base substrate 40 through an adhesive material. In addition, the external connectors 49 (e.g., solder balls) are formed or disposed on the second surface 402 for external connection.

During a manufacturing process, when the heat sink 46 is attached to the package structure 3, a pressing force may be transmitted from the heat sink 46 to the package structure 3. Since, the reinforcement structure 37 may increase the rigidity or stiffness of the package structure 3, a warpage of the package structure 3 may be reduced. Therefore, the reliability and yield of the assembly structure 4 is improved.

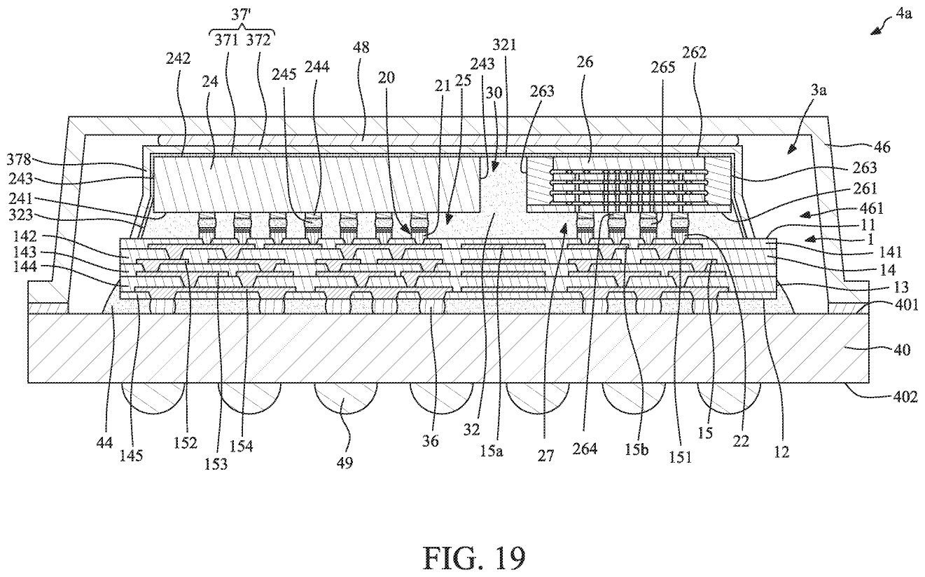

FIG. 19 illustrates a cross-sectional view of an assembly structure 4a according to some embodiments of the present disclosure. The assembly structure 4a of FIG. 19 is similar to the assembly structure 4 of FIG. 18, except that the package structure 3 is replaced by the package structure 3a of FIG. 8.

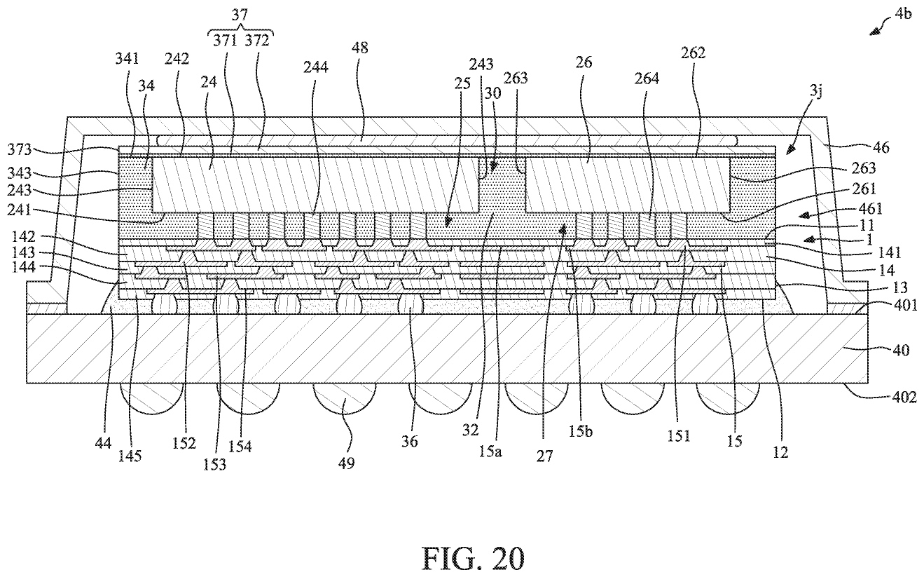

FIG. 20 illustrates a cross-sectional view of an assembly structure 4b according to some embodiments of the present disclosure. The assembly structure 4b of FIG. 20 is similar to the assembly structure 4 of FIG. 18, except that the package structure 3 is replaced by the package structure 3j of FIG. 17.

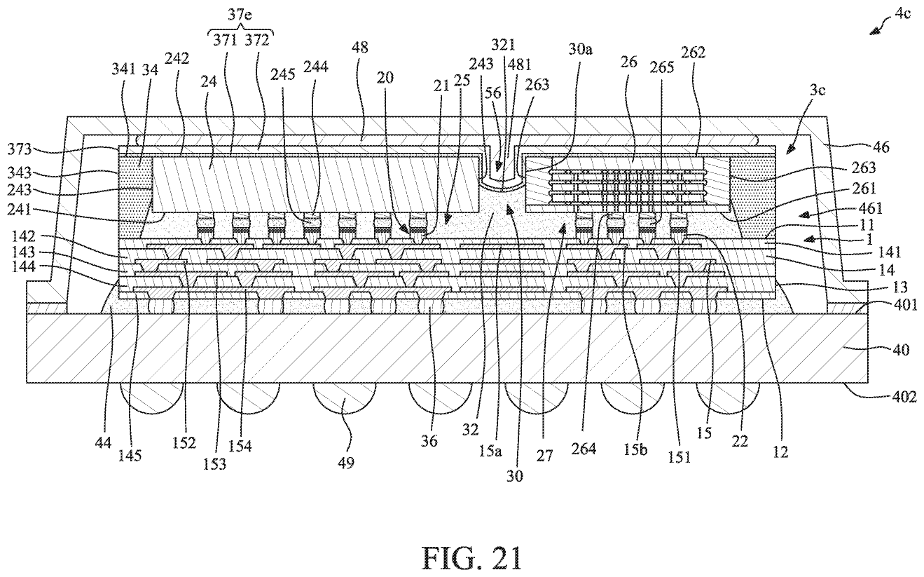

FIG. 21 illustrates a cross-sectional view of an assembly structure 4c according to some embodiments of the present disclosure. The assembly structure 4c of FIG. 21 is similar to the assembly structure 4 of FIG. 18, except that the package structure 3 is replaced by the package structure 3c of FIG. 10. In addition, thermal material 48 may be a sintered material, a glue material or a solder material. A portion 481 of the thermal material 48 may extend into the trench 56 defined by the reinforcement structure 37e in the groove 30a (or the gap 30).

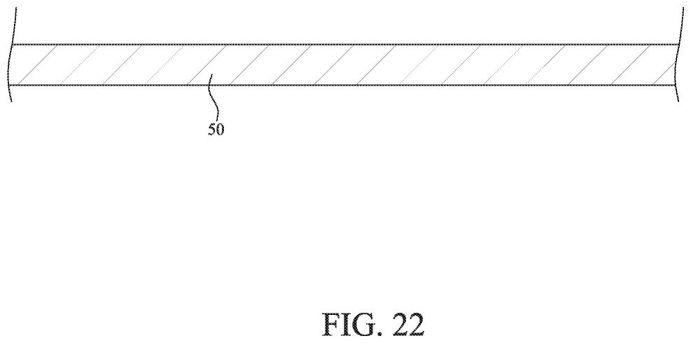

FIG. 22 through FIG. 33 illustrate a method for manufacturing an assembly structure according to some embodiments of the present disclosure. In some embodiments, the method is for manufacturing the package structure 3 shown in FIG. 1 to FIG. 4, and the assembly structure 4 of FIG. 18.

Referring to FIG. 22, a carrier 50 is provided. The carrier 50 may be in a wafer type or strip type.

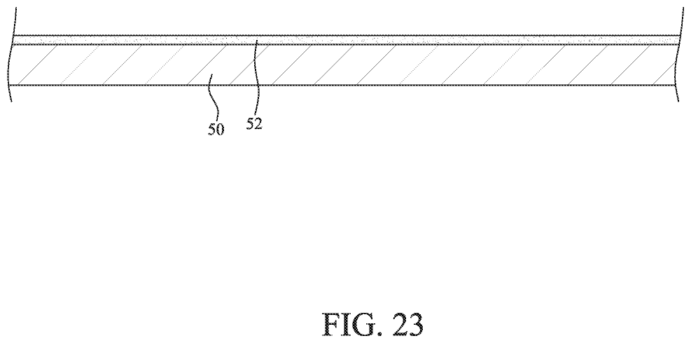

Referring to FIG. 23, a release layer 52 is formed or disposed on the carrier 50.

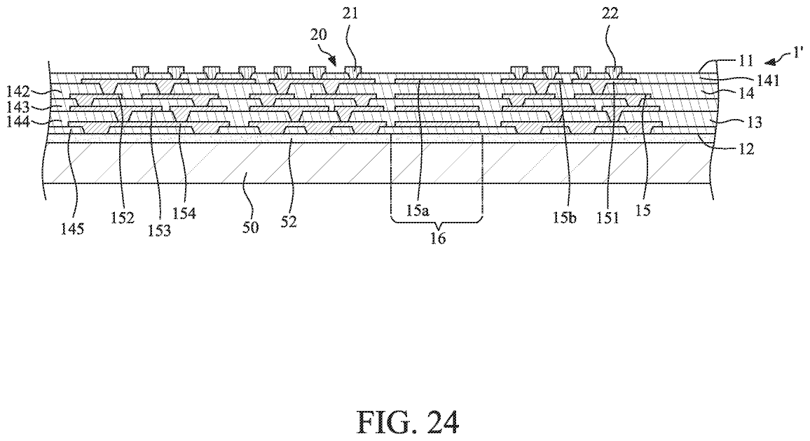

Referring to FIG. 24, a wiring structure 1′ is formed or disposed on the release layer 52 on the carrier 50. The wiring structure 1′ of FIG. 24 may be similar to the wiring structure 1 of FIG. 2, and may have a first surface 11, a second surface 12 opposite to the first surface 11, and a high density region 16 (or a fine line region). The wiring structure 1′ may include at least one dielectric layer 14 and at least one circuit layer 15 in contact with the dielectric layer 14 and a plurality of protrusion pads 20.

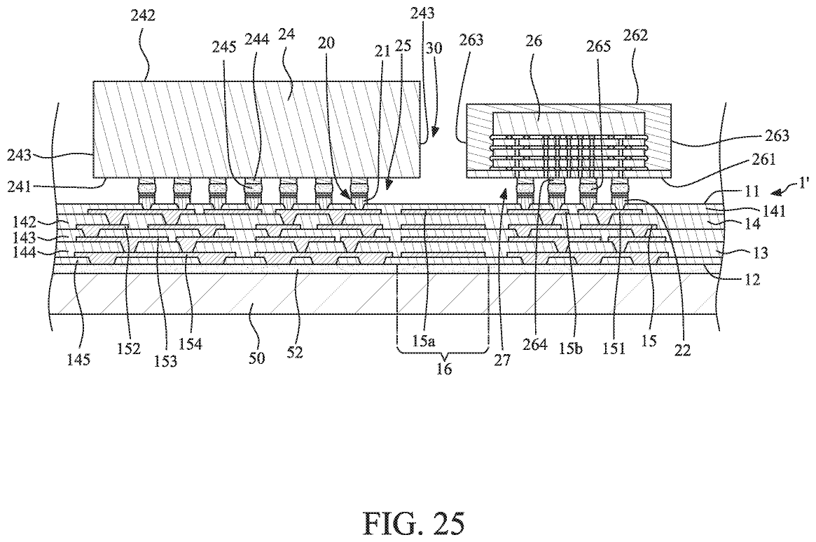

Referring to FIG. 25, a first electronic device 24 and a second electronic device 26 are electrically connected to the circuit layer 15 of the wiring structure 1′ by flip-chip bonding. Thus, the second electronic device 26 may be electrically connected to the first electronic device 24 through the interconnection portion 15a of the circuit layer 15 (including, for example, the interconnection portions 15a of the first circuit layer 151, the second circuit layer 152, the third circuit layer 153 and the fourth circuit layer 154). In some embodiments, the first electrical contacts 244 of the first electronic device 24 may be electrically connected and physically connected to the first protrusion pads 21 through a plurality of solder materials 245. Further, the second electrical contacts 264 of the second electronic device 26 may be electrically connected and physically connected to the second protrusion pads 22 through a plurality of solder materials 265.

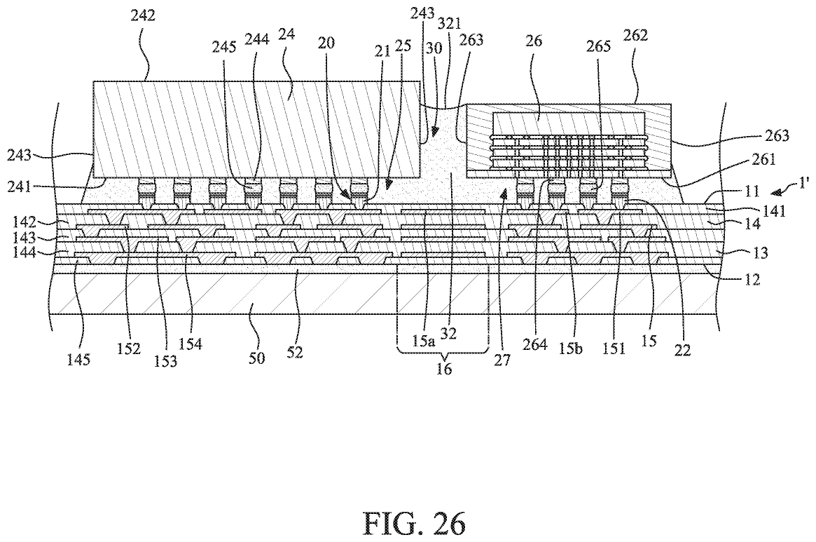

Referring to FIG. 26, a first protection material 32 (e.g., an underfill) is formed or disposed in a first space 25 between the first electronic device 24 and the wiring structure 1′ and a second space 27 between the second electronic device 26 and the wiring structure 1′ so as to cover and protect the joints formed by the first electrical contacts 244, the first protrusion pads 21 and the solder materials 245, and the joints formed by the second electrical contacts 264, the second protrusion pads 22 and the solder materials 265. In addition, the first protection material 32 may further extend into a gap 30 between the lateral side surface 243 of the first electronic device 24 and the lateral side surface 263 of the second electronic device 26.

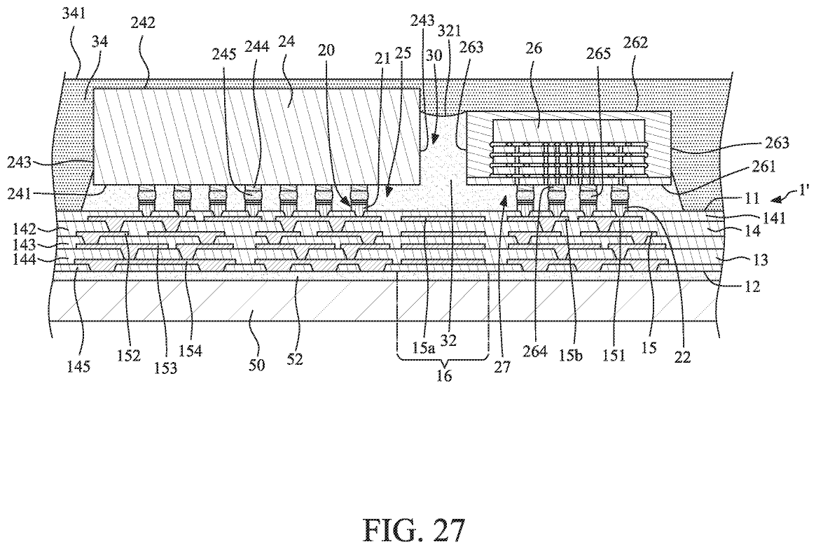

Referring to FIG. 27, an encapsulant 34 is formed or disposed to cover at least a portion of the first surface 11 of the wiring structure 1′, at least a portion of the first electronic device 24, at least a portion of the second electronic device 26 and the first protection material 32. The encapsulant 34 has a first surface 341 (e.g., a top surface).

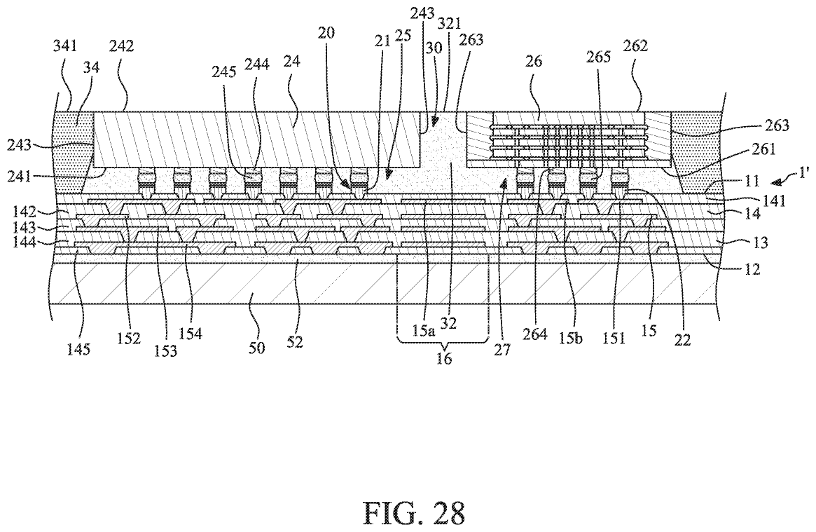

Referring to FIG. 28, a grinding process is conducted so that the first surface 341 of the encapsulant 34, the second surface 242 of the first electronic device 24, the second surface 262 of the second electronic device 26 and the top surface 321 of the first protection material 32 in the gap 30 may be substantially coplanar with each other.

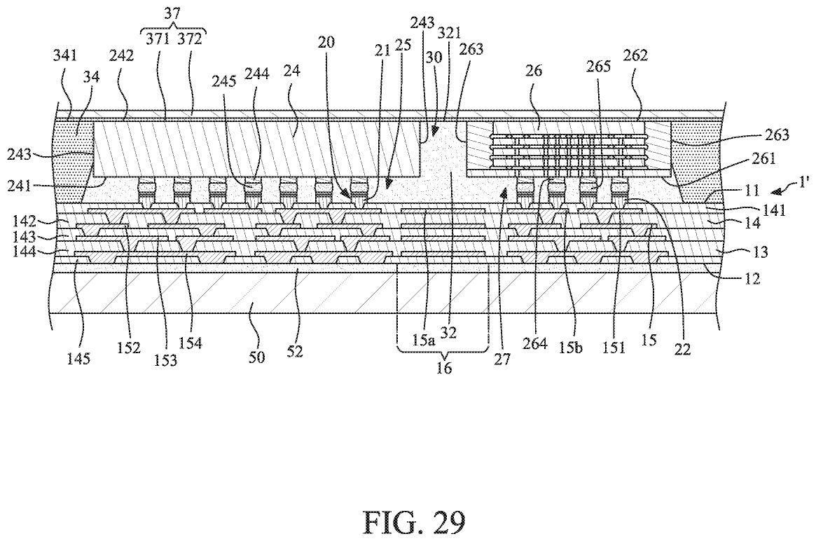

Referring to FIG. 29, a reinforcement structure 37 is formed or disposed on the first surface 341 of the encapsulant 34, the second surface 242 of the first electronic device 24, the second surface 262 of the second electronic device 26 and the top surface 321 of the first protection material 32. In some embodiments, the reinforcement structure 37 may be formed by plating or coating such as physical vapor deposition (PVD). The reinforcement structure 37 of FIG. 29 may be similar to the reinforcement structure 37 of FIG. 2.

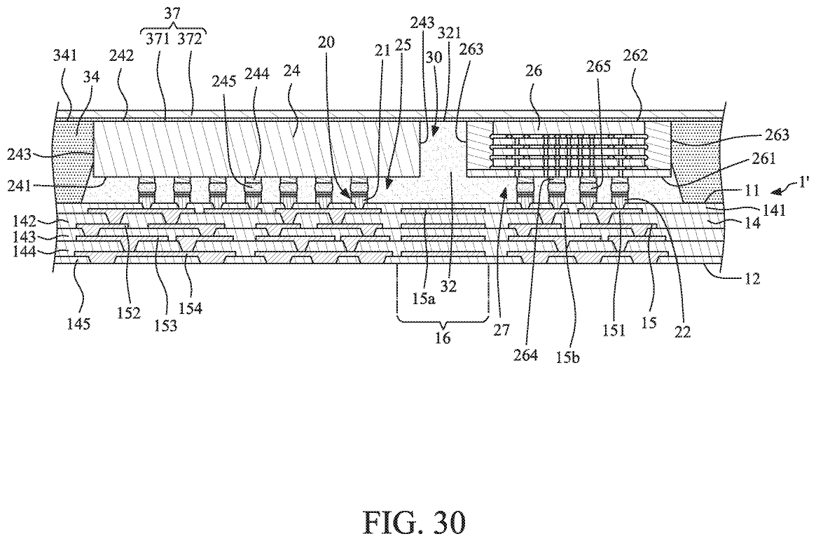

Referring to FIG. 30, the carrier 50 and the release layer 52 are removed. Thus, portions (e.g., the bottom portions of the via portions) of the fourth circuit layer 154 are exposed from the second surface 12 of the wiring structure 1′.

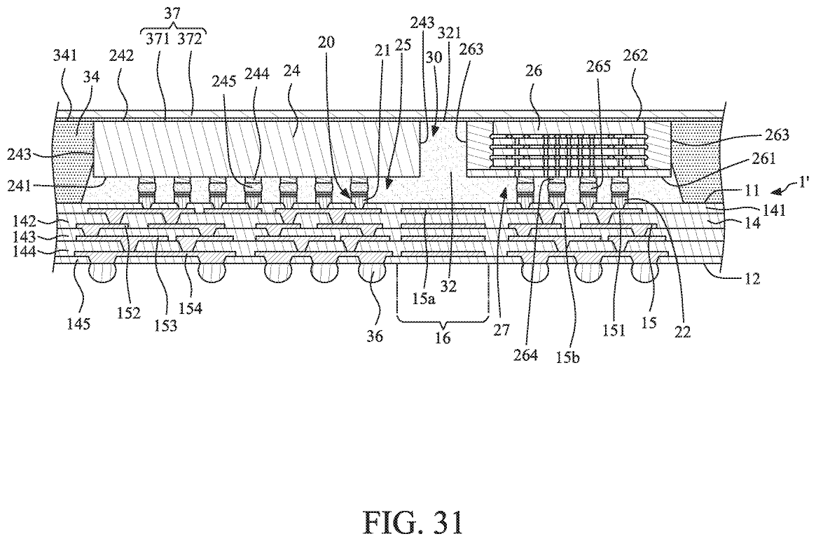

Referring to FIG. 31, a plurality of solder materials 36 (e.g., solder balls) are formed or disposed to the second surface 12 of the wiring structure 1′. As shown in FIG. 31, the solder materials 36 are disposed on the exposed portions (e.g., the bottom portions of the via portions) of the fourth circuit layer 154.

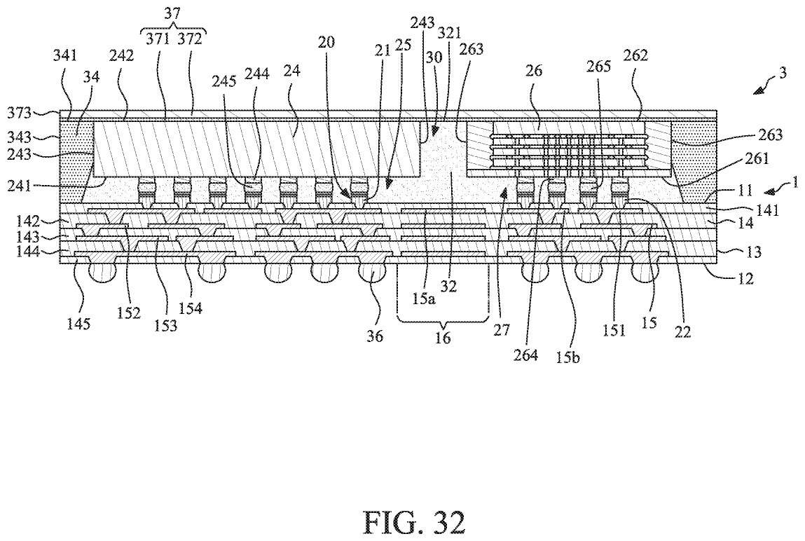

Referring to FIG. 32, a singulation process may be conducted to the wiring structure 1′ so as to obtain a plurality of package structures 3 shown in FIG. 1 to FIG. 4.

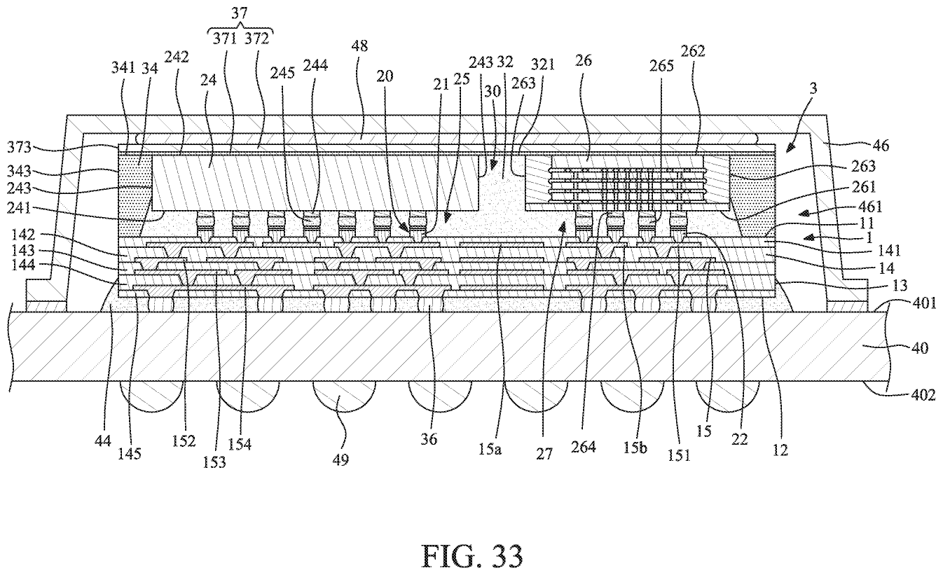

Referring to FIG. 33, the package structure 3 may be electrically connected to a first surface 401 of a base substrate 40 through the solder materials 36. Then, a second protection material 44 (e.g., an underfill) is formed or disposed in a space between the package structure 3 and the base substrate 40 so as to cover and protect the solder materials 36. Then, a heat sink 46 may be attached to the first electronic device 24, the second electronic device 26 and the base substrate 40. A portion of the heat sink 46 may be attached to the top surface of the package structure 3 through a thermal material 48 (e.g., thermal interface material (TIM)). Another portion (e.g., bottom portion) of the heat sink 46 may be attached to the base substrate 40 through an adhesive material. Then, a plurality of external connectors 49 (e.g., solder balls) may be formed or disposed on the second surface 402 of the base substrate 40 for external connection.

Then, a singulation process may be conducted to the base substrate 40 so as to obtain a plurality of assembly structures 4 shown in FIG. 18.

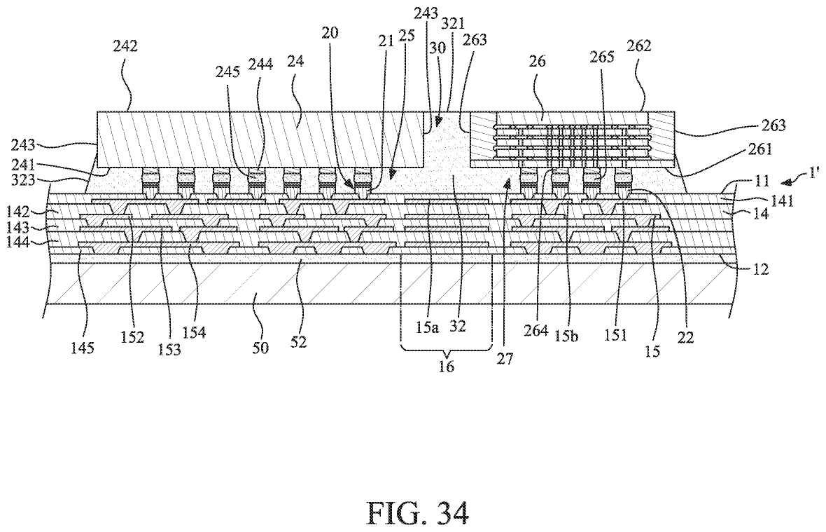

FIG. 34 through FIG. 37 illustrate a method for manufacturing a package structure according to some embodiments of the present disclosure. In some embodiments, the method is for manufacturing the package structure 3a shown in FIG. 8, and the assembly structure 4a of FIG. 19. The initial stages of the illustrated process are the same as, or similar to, the stages illustrated in FIG. 22 to FIG. 26. FIG. 34 depicts a stage subsequent to that depicted in FIG. 26.

Referring to FIG. 34, a grinding process is conducted so that the second surface 242 of the first electronic device 24, the second surface 262 of the second electronic device 26 and the top surface 321 of the first protection material 32 in the gap 30 may be substantially coplanar with each other. Meanwhile, the first protection material 32 has an outer side surface 323.

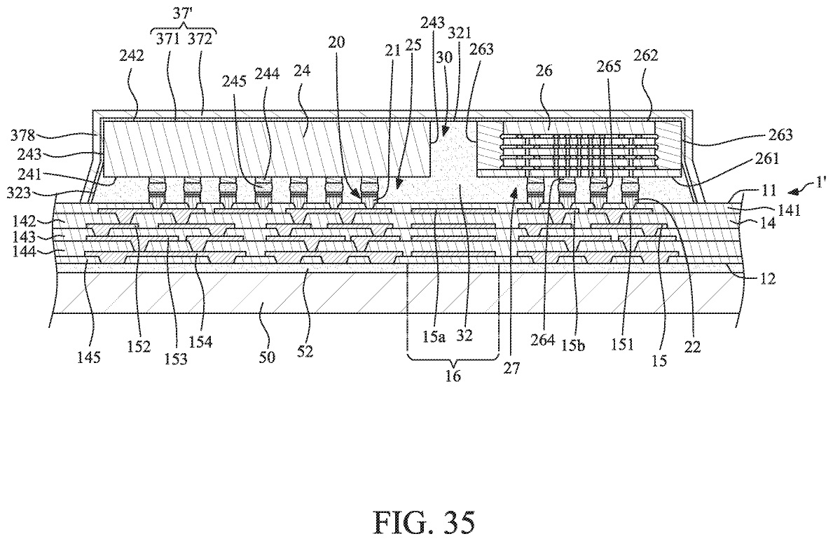

Referring to FIG. 35, a reinforcement structure 37′ is formed or disposed on the second surface 242 of the first electronic device 24, the second surface 262 of the second electronic device 26, the top surface 321 and the outer side surface 323 of the first protection material 32. In some embodiments, the reinforcement structure 37′ may be formed by plating or coating such as physical vapor deposition (PVD). The reinforcement structure 37′ of FIG. 35 may be similar to the reinforcement structure 37′ of FIG. 8.

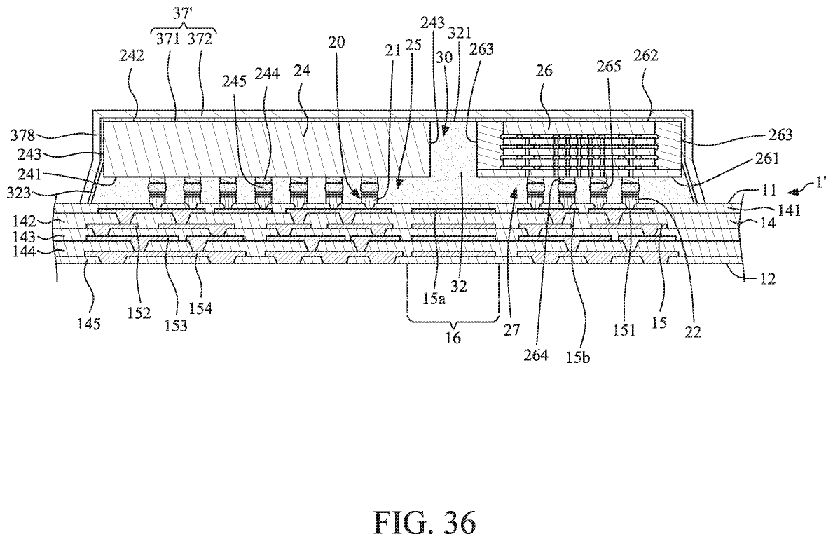

Referring to FIG. 36, the carrier 50 and the release layer 52 are removed. Thus, portions (e.g., the bottom portions of the via portions) of the fourth circuit layer 154 are exposed from the second surface 12 of the wiring structure 1′.

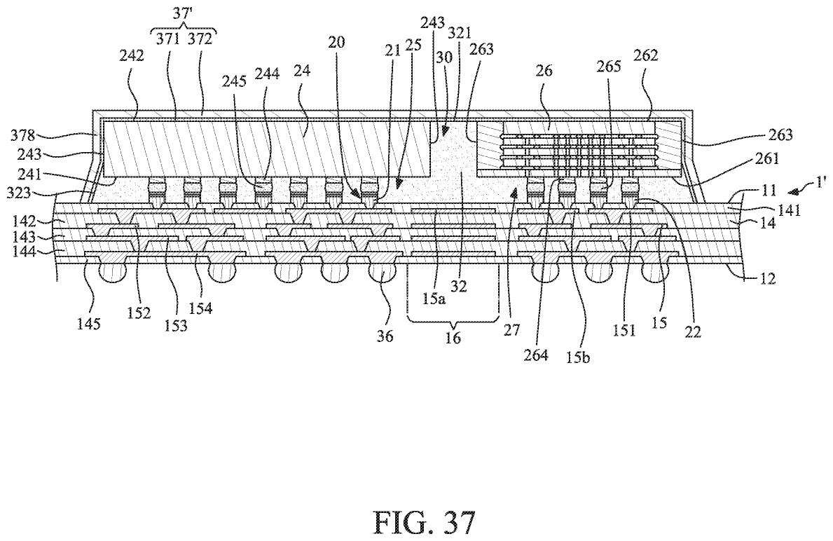

Referring to FIG. 37, a plurality of solder materials 36 (e.g., solder balls) are formed or disposed to the second surface 12 of the wiring structure 1′.

Then, a singulation process may be conducted to the wiring structure 1′ so as to obtain a plurality of package structures 3a shown in FIG. 8.

Then, the package structure 3 may be electrically connected to a first surface 401 of a base substrate 40 through the solder materials 36. Then, a second protection material 44 (e.g., an underfill) is formed or disposed in a space between the package structure 3 and the base substrate 40 so as to cover and protect the solder materials 36. Then, a heat sink 46 may be attached to the first electronic device 24, the second electronic device 26 and the base substrate 40. Then, a singulation process may be conducted to the base substrate 40 so as to obtain a plurality of assembly structures 4a shown in FIG. 19.

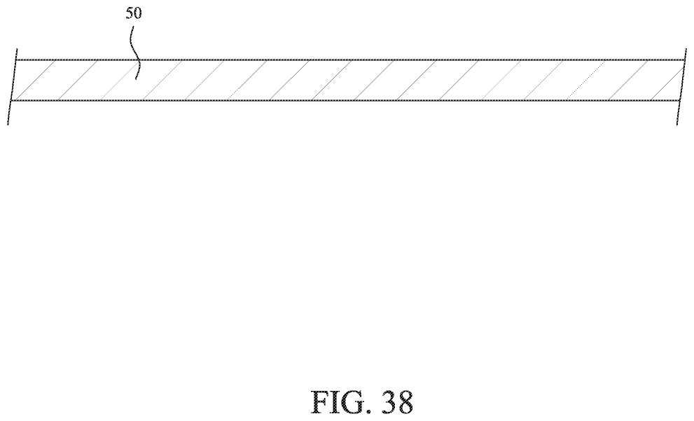

FIG. 38 through FIG. 46 illustrate a method for manufacturing a package structure according to some embodiments of the present disclosure. In some embodiments, the method is for manufacturing the package structure 3j shown in FIG. 17, and the assembly structure 4b of FIG. 20.

Referring to FIG. 38, a carrier 50 is provided. The carrier 50 may be in a wafer type or strip type.

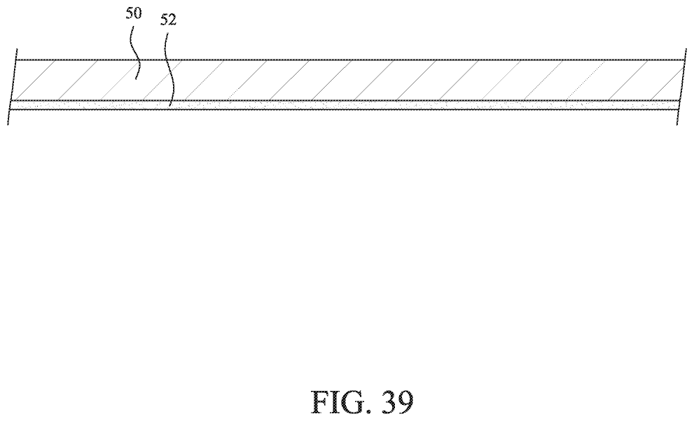

Referring to FIG. 39, a release layer 52 is formed or disposed on the carrier 50.

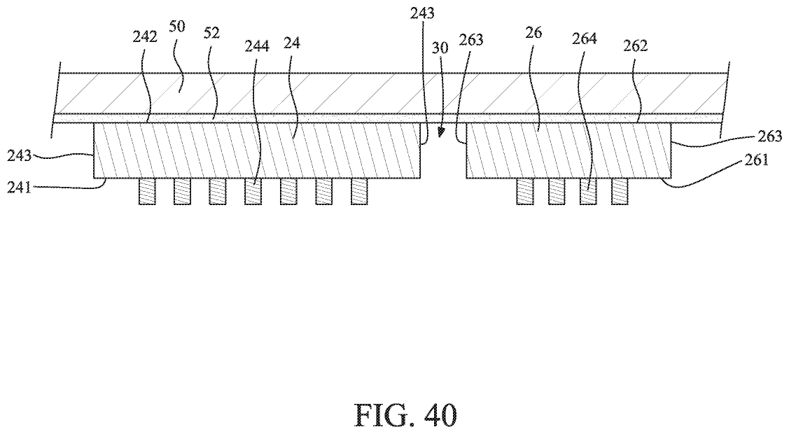

Referring to FIG. 40, a first electronic device 24 and a second electronic device 26 are attached to the release layer 52 on the carrier 50 side by side.

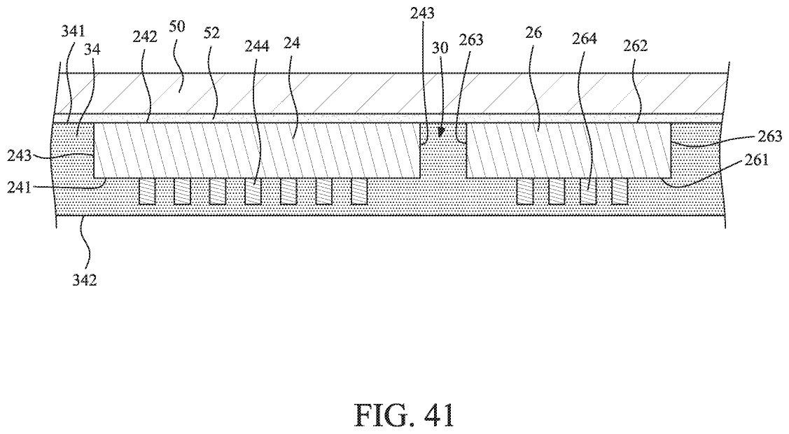

Referring to FIG. 41, an encapsulant 34 is formed or disposed to cover at least a portion of the release layer 52 on the carrier 50, the first electronic device 24 and the second electronic device 26. The encapsulant 34 has a first surface 341 (e.g., a top surface) and a second surface 342 (e.g., a bottom surface).

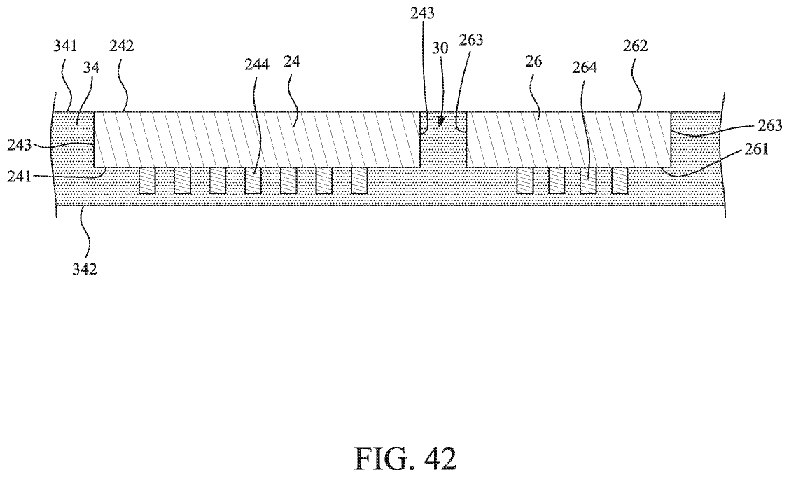

Referring to FIG. 42, the release layer 52 and the carrier 50 are removed.

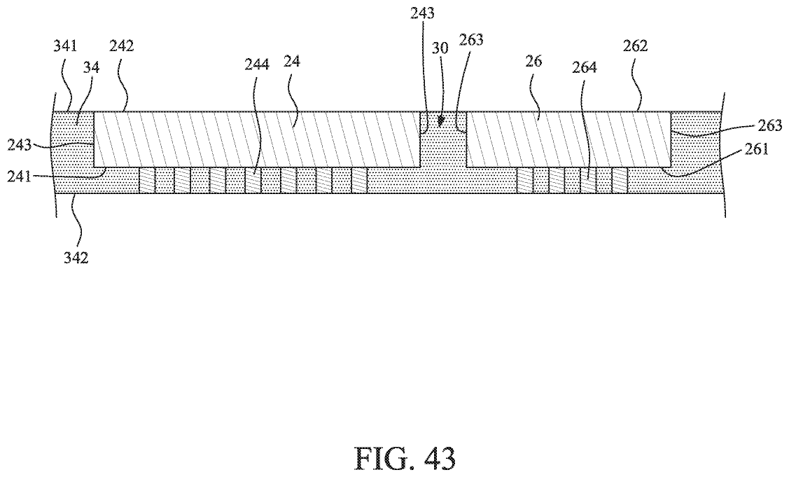

Referring to FIG. 43, a grinding process is conducted so that the second surface 342 of the encapsulant 34 may be substantially coplanar with the bottom surfaces of the first electrical contacts 244 and the second electrical contacts 264.

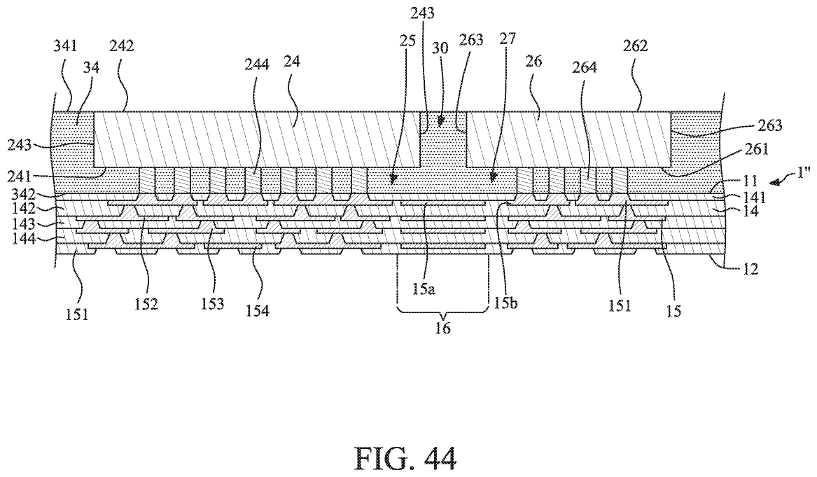

Referring to FIG. 44, a wiring structure 1″ is formed or disposed on the second surface 342 of the encapsulant 34. The wiring structure 1″ of FIG. 44 may be similar to the wiring structure 1b of FIG. 17, and may have a first surface 11, a second surface 12 opposite to the first surface 11, and a high density region 16 (or a fine line region). The wiring structure 1″ may include at least one dielectric layer 14 and at least one circuit layer 15 in contact with the dielectric layer 14. For example, the first dielectric layer 141 may contact the encapsulant 34. The first circuit layer 151 may be disposed on the first dielectric layer 141. A portion (e.g., a via portion) of the first circuit layer 151 may extend through the first dielectric layer 141 to electrically connect the first electrical contacts 244 and the second electrical contacts 264.

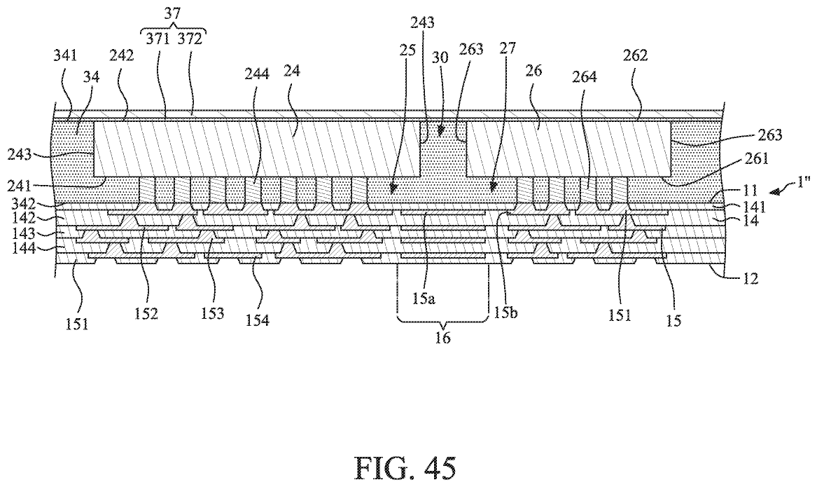

Referring to FIG. 45, a reinforcement structure 37 is formed or disposed on the first surface 341 of the encapsulant 34, the second surface 242 of the first electronic device 24 and the second surface 262 of the second electronic device 26. In some embodiments, the reinforcement structure 37 may be formed by plating or coating such as physical vapor deposition (PVD). The reinforcement structure 37 of FIG. 45 may be similar to the reinforcement structure 37 of FIG. 17.

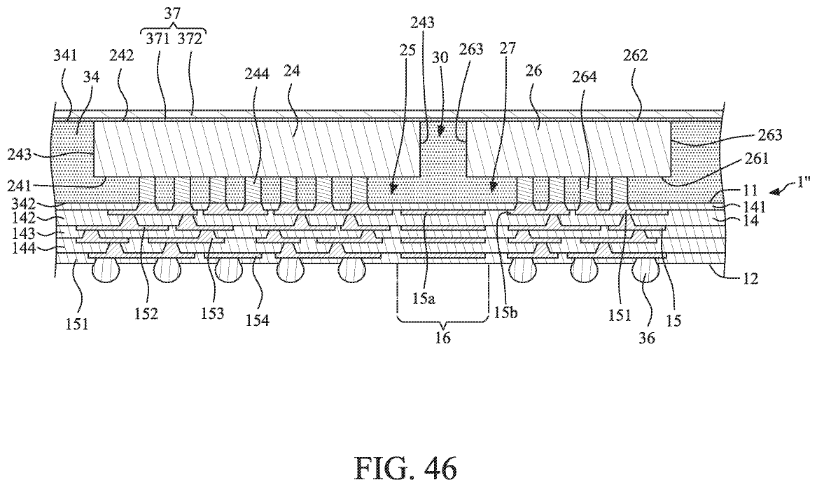

Referring to FIG. 46, a plurality of solder materials 36 (e.g., solder balls) are formed or disposed to the second surface 12 of the wiring structure 1″.

Then, a singulation process may be conducted to the wiring structure 1″ so as to obtain a plurality of package structures 3j shown in FIG. 17.

Then, the package structure 3j may be electrically connected to a first surface 401 of a base substrate 40 through the solder materials 36. Then, a second protection material 44 (e.g., an underfill) is formed or disposed in a space between the package structure 3j and the base substrate 40 so as to cover and protect the solder materials 36. Then, a heat sink 46 may be attached to the first electronic device 24, the second electronic device 26 and the base substrate 40. Then, a singulation process may be conducted to the base substrate 40 so as to obtain a plurality of assembly structures 4b shown in FIG. 20.

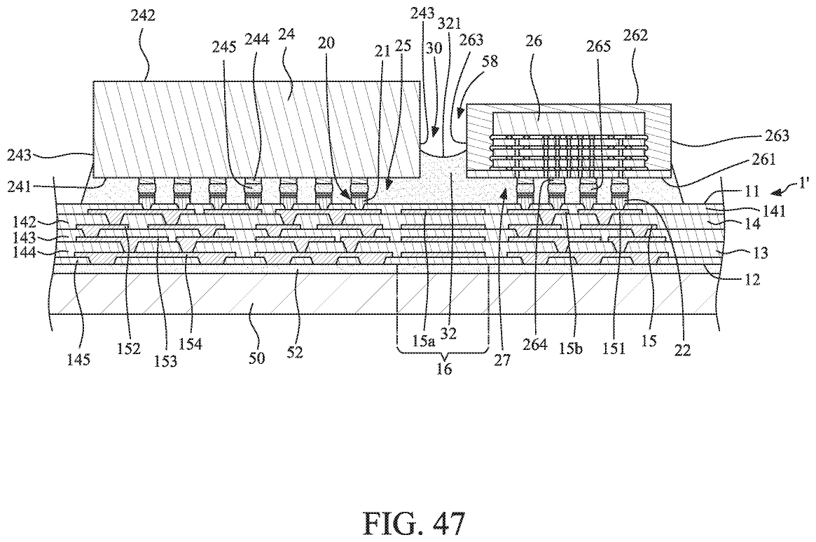

FIG. 47 through FIG. 52 illustrate a method for manufacturing a package structure according to some embodiments of the present disclosure. In some embodiments, the method is for manufacturing the package structure 3c shown in FIG. 10, and the assembly structure 4c of FIG. 21. The initial stages of the illustrated process are the same as, or similar to, the stages illustrated in FIG. 22 to FIG. 25. FIG. 47 depicts a stage subsequent to that depicted in FIG. 25.

Referring to FIG. 47, a first protection material 32 (e.g., an underfill) is formed or disposed in a first space 25 between the first electronic device 24 and the wiring structure 1′ and a second space 27 between the second electronic device 26 and the wiring structure 1′. In addition, the first protection material 32 may further extend into the gap 30. As shown in FIG. 47, the first protection material 32 in the gap 30 may not reach to the level of the second surface 242 of the first electronic device 24 and/or the second surface 262 of the second electronic device 26. Thus, there is a recess portion 58 defined by the lateral side surface 243 of the first electronic device 24, the top surface 321 of the first protection material 32 and the lateral side surface 263 of the second electronic device 26. The recess portion 58 may be a portion of the gap 30.

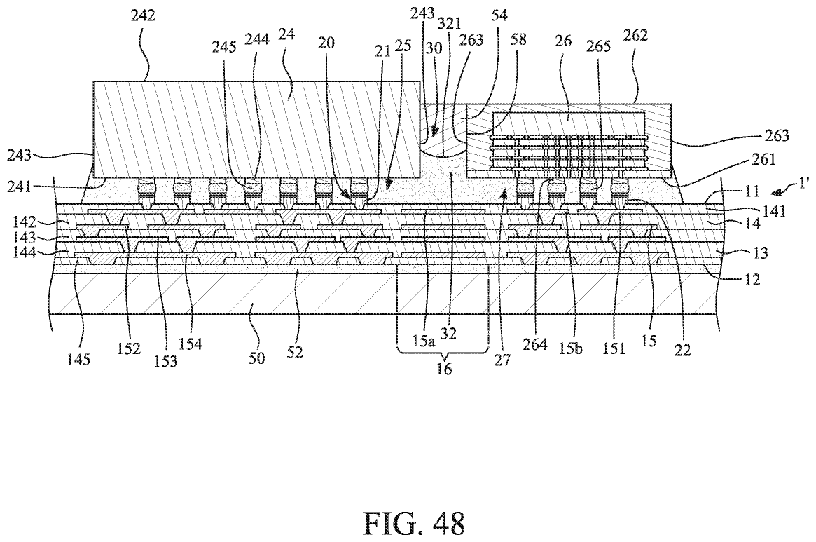

Referring to FIG. 48, a temporary structure 54 is formed or disposed in the recess portion 58. The temporary structure 54 may be a removable glue.

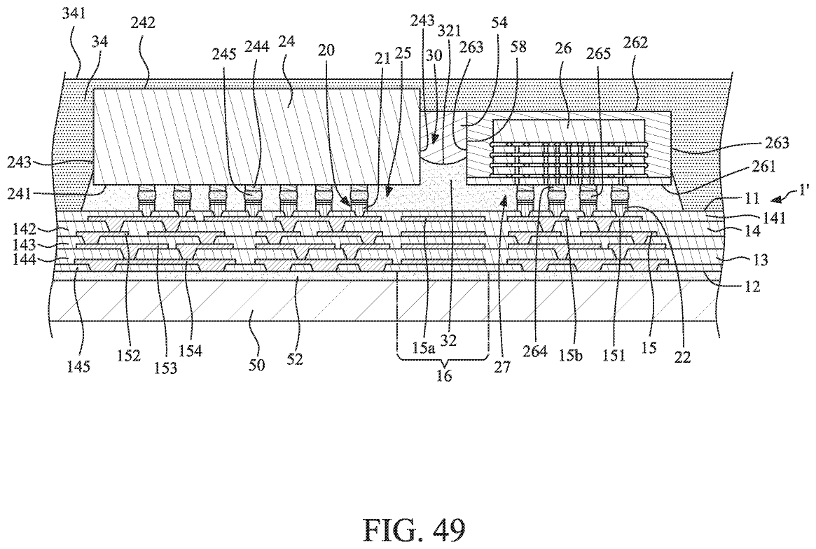

Referring to FIG. 49, an encapsulant 34 is formed or disposed to cover at least a portion of the first surface 11 of the wiring structure 1′, at least a portion of the first electronic device 24, at least a portion of the second electronic device 26, the temporary structure 54 and the first protection material 32. The encapsulant 34 has a first surface 341 (e.g., a top surface).

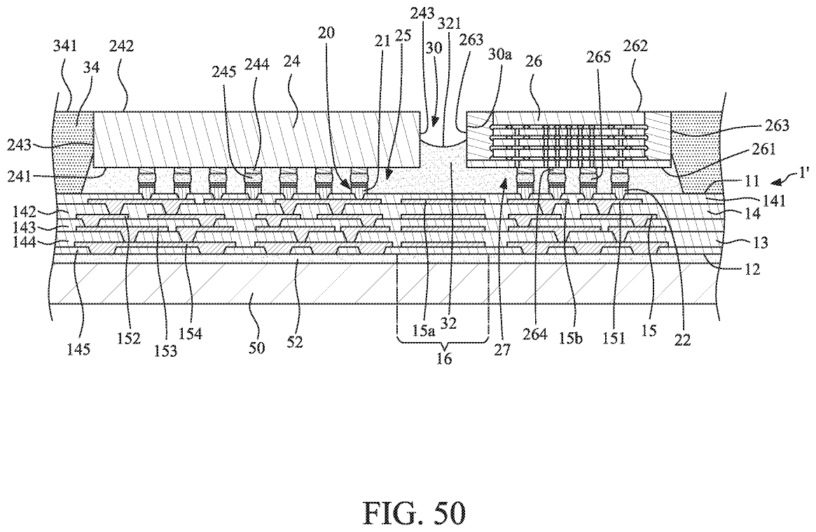

Referring to FIG. 50, the encapsulant 34, the first electronic device 24 and/or the second electronic device 26 are thinned to expose the temporary structure 54. In some embodiments, a grinding process is conducted so that the first surface 341 of the encapsulant 34, the second surface 242 of the first electronic device 24, the second surface 262 of the second electronic device 26 and a top surface of the temporary structure 54 may be substantially coplanar with each other. Then, the temporary structure 54 is removed so as to form a groove 30a defined by the lateral side surface 243 of the first electronic device 24, the top surface 321 of the first protection material 32 and the lateral side surface 263 of the second electronic device 26.

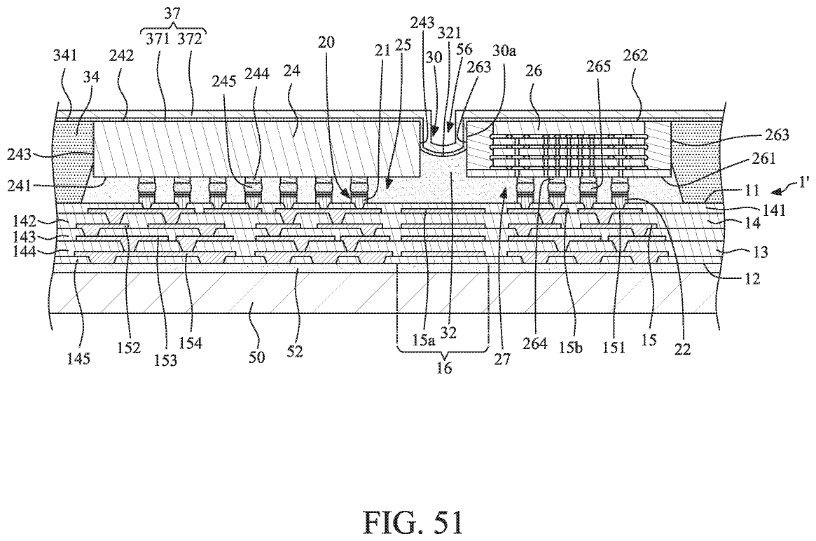

Referring to FIG. 51, a reinforcement structure 37e is formed or disposed on the first surface 341 of the encapsulant 34, the second surface 242 of the first electronic device 24, the second surface 262 of the second electronic device 26. In some embodiments, the reinforcement structure 37e may be formed by plating or coating such as physical vapor deposition (PVD). The reinforcement structure 37e of FIG. 51 may be similar to the reinforcement structure 37e of FIG. 10. As shown in FIG. 51, a portion of the reinforcement structure 37e may extend into the groove 30a (or the gap 30) to contact the top surface 321 of the first protection material 32. In addition, the portion of the reinforcement structure 37e in the groove 30a (or the gap 30) may define a trench 56.

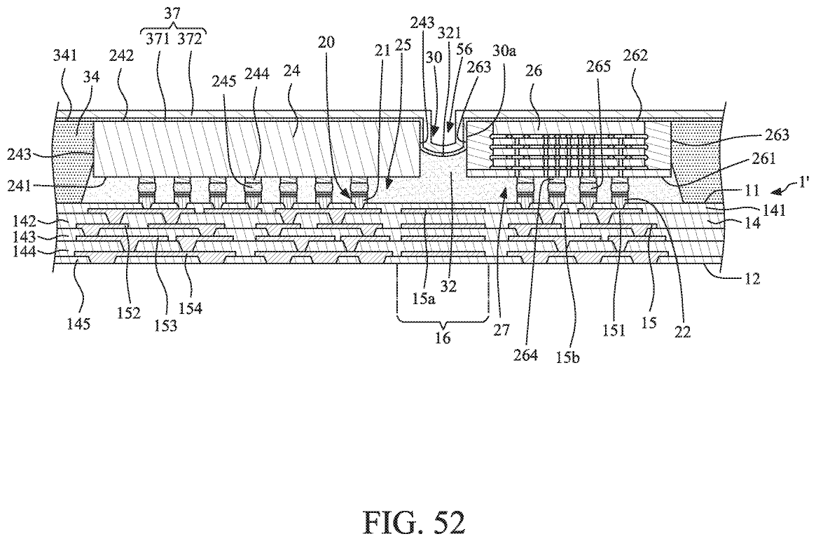

Referring to FIG. 52, the carrier 50 and the release layer 52 are removed. Thus, portions (e.g., the bottom portions of the via portions) of the fourth circuit layer 154 are exposed from the second surface 12 of the wiring structure 1′. Then, a plurality of solder materials 36 (e.g., solder balls) are formed or disposed to the second surface 12 of the wiring structure 1′. Then, a singulation process may be conducted to the wiring structure 1′ so as to obtain a plurality of package structures 3c shown in FIG. 10.

Then, the package structure 3c may be electrically connected to a first surface 401 of a base substrate 40 through the solder materials 36. Then, a second protection material 44 (e.g., an underfill) is formed or disposed in a space between the package structure 3c and the base substrate 40 so as to cover and protect the solder materials 36. Then, a heat sink 46 may be attached to the first electronic device 24, the second electronic device 26 and the base substrate 40. A portion of the heat sink 46 may be attached to the top surface of the package structure 3 through a thermal material 48 (e.g., thermal interface material (TIM)). Thermal material 48 may be a sintered material, a glue material or a solder material. A portion 481 of the thermal material 48 may extend into the trench 56.

Then, a plurality of external connectors 49 (e.g., solder balls) may be formed or disposed on the second surface 402 of the base substrate 40 for external connection. Then, a singulation process may be conducted to the base substrate 40 so as to obtain a plurality of assembly structures 4c shown in FIG. 21.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
a wiring structure;
a first electronic device electrically connected to the wiring structure;
a second electronic device electrically connected to the wiring structure;
a protection material disposed between the first electronic device and the wiring structure and between the second electronic device and the wiring structure; and
a reinforcement structure disposed on and contacting the first electronic device and the second electronic device, wherein the reinforcement structure contacts the protection material.

2. The package structure of claim 1, wherein a portion of the reinforcement structure extends into a gap between the first electronic device and the second electronic device.

3. The package structure of claim 2, wherein the reinforcement structure includes a first reinforcement portion disposed on and contacting the first electronic device and the second electronic device, and a second reinforcement portion disposed in the gap.

4. The package structure of claim 2, wherein the protection material extends from a first space between the first electronic device and the wiring structure to a second space between the second electronic device and the wiring structure, wherein the protection material further extends into the gap between the first electronic device and the second electronic device.

5. The package structure of claim 1, wherein the reinforcement structure contacts the wiring structure.

6. The package structure of claim 1, wherein the reinforcement structure further contacts a lateral side surface of the first electronic device and a lateral side surface of the second electronic device.

7. The package structure of claim 1, wherein the reinforcement structure is a monolithic structure.

8. The package structure of claim 1, wherein a top surface of the protection material is substantially coplanar with a second surface of the first electronic device and a second surface of the second electronic device.

9. The package structure of claim 8, wherein the protection material has at least one crack on a top surface thereof, and a portion of the reinforcement structure extends into the crack.

10. The package structure of claim 1, wherein the wiring structure has a first surface, a second surface opposite to the first surface, and a lateral side surface extending between the first surface and the second surface, the first electronic device and the second electronic device are disposed adjacent to the first surface of the wiring structure, the package structure further comprises a third electronic device disposed adjacent to the second surface of the wiring structure, and a package body covering the third electronic device, wherein the reinforcement structure is further disposed on and contacts the lateral side surface of the wiring structure and a lateral side surface of the package body.

11. The package structure of claim 1, wherein a surface condition of a bottom surface of the reinforcement structure is consistent with the surface conditions of a top surface of the protection material, a second surface of the first electronic device and a second surface of the second electronic device.

12. A package structure, comprising:
a wiring structure;
a first electronic device electrically connected to the wiring structure;
a second electronic device electrically connected to the wiring structure;
a protection material extending from a first space between the first electronic device and the wiring structure to a second space between the second electronic device and the wiring structure;
a reinforcement structure disposed on the first electronic device and the second electronic device; and
a buffer structure disposed between the reinforcement structure and the protection material.

13. The package structure of claim 12, wherein the buffer structure is an empty space.

14. The package structure of claim 12, wherein the buffer structure is a portion of the reinforcement structure.

15. The package structure of claim 14, wherein the reinforcement structure contacts the first electronic device, the second electronic device and the protection material.

16. The package structure of claim 12, wherein a top surface of the protection material is substantially coplanar with a second surface of the first electronic device and a second surface of the second electronic device.

17. The package structure of claim 12, further comprising an encapsulant covering the first electronic device, the second electronic device and the protection material, wherein a top surface of the encapsulant is substantially coplanar with a top surface of the protection material, a second surface of the first electronic device and a second surface of the second electronic device.

18. A manufacturing method, comprising:
(a) providing a wiring structure, wherein the wiring structure includes at least one dielectric layer and at least one circuit layer in contact with the dielectric layer;
(b) electrically connecting a first electronic device and a second electronic device to the wiring structure;
(c) forming a protection material in a first space between the first electronic device and the wiring structure and in a second space between the second electronic device and the wiring structure, wherein the protection material further extends into a gap between the first electronic device and the second electronic device; and
(d) forming a reinforcement structure on the first electronic device, the second electronic device and the protection material.

19. The manufacturing method of claim 18, wherein in (c), a recess portion is defined by a lateral side surface of the first electronic device, the top surface of the first protection material and the lateral side surface of the second electronic device;
wherein after (c), the method further comprises:
(c1) forming a temporary structure in the recess portion; and
(c2) forming an encapsulant to cover the first electronic device, the second electronic device and the temporary structure.

20. The manufacturing method of claim 19, wherein in after (c2), the method further comprises:
(c3) thinning the encapsulant, the first electronic device and the second electronic device to expose the temporary structure; and
(c4) removing the temporary structure to form a groove;
wherein in (d), a portion of the reinforcement structure extends into the groove to contact the top surface of the protection material.
